(19) United States
(12) Patent Application Publication
(10) Pub. No.: US 2023/0296820 A1
(43) Pub. Date: Sep. 21, 2023

(54) POLARIZING PLATE AND IMAGE DISPLAY DEVICE

(71) Applicant: FUJIFILM Corporation, Tokyo (JP)

(72) Inventors: Yuki NAKAMURA, Kanagawa (JP); Shuntaro IBUKI, Kanagawa (JP)

(73) Assignee: FUJIFILM Corporation, Tokyo (JP)

(21) Appl. No.: 18/322,299

(22) Filed: May 23, 2023

Related U.S. Application Data
(63) Continuation of application No. PCT/JP2021/042930, filed on Nov. 24, 2021.

(30) Foreign Application Priority Data
Nov. 26, 2020 (JP) 2020-196058

(51) Int. Cl. G02B 5/30; G02F 1/1335; H10K 59/80; C09K 19/04

(52) U.S. Cl. CPC G02B 5/3083; G02B 5/3016; G02B 5/305; G02F 1/133528; H10K 59/8793; C09K 19/04; C09K 2019/0448

(57) ABSTRACT

Provided is a polarizing plate having an excellent adhesiveness between a polarizer and an optical film and having good durability; and an image display device having the same. The polarizing plate includes a polarizer, an adhesive layer, and an optical film exhibiting reverse wavelength dispersibility, adjacent to each other in this order, in which the adhesive layer is a layer formed of an adhesive composition containing a polymerizable compound and a polymerization initiator, and the polarizing plate satisfies Condition 1: a maximum absorption wavelength of the polymerization initiator is within ±70 nm of a minimum absorption wavelength of the optical film and Condition 2: a molar absorption coefficient of the polymerization initiator is 22,000 mol⁻¹Lcm⁻¹ or more.

### CROSS-REFERENCE TO RELATED APPLICATIONS

This application is a Continuation of PCT International Application No. PCT/JP2021/042930 filed on Nov. 24, 2021, which claims priority under 35 U.S.C. § 119(a) to Japanese Patent Application No. 2020-196058 filed on Nov. 26, 2020. The above applications are hereby expressly incorporated by reference, in its entirety, into the present application.

### BACKGROUND OF THE INVENTION

### 1. Field of the Invention

The present invention relates to a polarizing plate and an image display device.

### 2. Description of the Related Art

A polymerizable liquid crystal compound exhibiting reverse wavelength dispersibility enables, for example, accurate conversion of light ray wavelengths over a wide wavelength range and reduction in the thickness of an optical film (phase difference film) due to its high refractive index, and therefore, it has been actively studied.

For example, JP2017-194571A describes a polarizing film having a phase difference film and a polarizer, laminated through an adhesive layer ([Claim 1] and [Claim 20]).

### SUMMARY OF THE INVENTION

The present inventors have conducted studies on a known polarizing plate described in JP2017-194571A and the like, that is, a polarizing plate having a polarizer, an adhesive layer, and an optical film exhibiting reverse wavelength dispersibility, adjacent to each other in this order, and have thus clarified that the adhesiveness between the polarizer and the optical film is insufficient, and there is room for improvement in durability.

Therefore, an object of the present invention is to provide a polarizing plate having an excellent adhesiveness between a polarizer and an optical film and having good durability; and an image display device having the same.

The present inventors have conduced intensive studies to accomplish the object, and as a result, they have thus found that a polarizing plate having an excellent adhesiveness between a polarizer and an optical film and having good durability can be manufactured by adjusting a maximum absorption wavelength of a polymerization initiator included in an adhesive composition forming an adhesive layer to be in a predetermined range, and adjusting a molar absorption coefficient to equal to or more than a predetermined value, thereby completing the present invention.

That is, the present inventors have found that the object can be accomplished by the following configurations.
[1] A polarizing plate comprising, adjacently in the following order: a polarizer; an adhesive layer; and an optical film exhibiting reverse wavelength dispersibility, in which the adhesive layer is a layer formed of an adhesive composition containing a polymerizable compound and a polymerization initiator, and
the polarizing plate satisfies conditions 1 and 2 shown below,
condition 1: a maximum absorption wavelength of the polymerization initiator is within ±70 nm of a minimum absorption wavelength of the optical film, and
condition 2: a molar absorption coefficient of the polymerization initiator is 22,000 mol⁻¹Lcm⁻¹ or more.
[2] The polarizing plate as described in [1], in which the optical film has an optically anisotropic layer formed of a polymerizable liquid crystal composition containing a polymerizable liquid crystal compound.
[3] The polarizing plate as described in [2], in which the polymerizable liquid crystal compound is a compound having a linking group represented by any of Formulae (Ar-1) to (Ar-7) which will be described later.
[4] The polarizing plate as described in any one of [1] to [3], in which a polymer having a repeating unit represented by Formula (B) which will be described later is present on a surface of the optical film on the adhesive layer side or a surface of the adhesive layer on the optical film side.
[5] The polarizing plate as described in [4], in which the polymer is a copolymer further having a repeating unit represented by Formula (F) which will be described later.
[6] The polarizing plate as described in [4] or [5], in which the polymer is present on a surface of the optical film on the adhesive layer side.
[7] The polarizing plate as described in any one of [1] to [6], in which the optical film has at least one optically anisotropic layer where a liquid crystal state of a smectic phase is immobilized.
[8] The polarizing plate as described in any one of [1] to [7], in which the adhesive composition further contains a sensitizer, and the sensitizer has a maximum absorption wavelength that is on a longer wavelength side than a maximum absorption wavelength of the polymerization initiator and in a wavelength range where a transmittance of the optical film is 1% or more.
[9] The polarizing plate as described in any one of [1] to [8], in which the polymerizable compound is a cationically polymerizable compound.
[10] The polarizing plate as described in any one of [1] to [8], in which the polymerizable compound is a radically polymerizable compound.
[11] An image display device comprising the polarizing plate as described in any one of [1] to [10].
[12] The image display device as described in [11], in which the image display device is a liquid crystal display device.
[13] The image display device as described in [11], which is an organic electroluminescent display device.

According to the present invention, it is possible to provide a polarizing plate having an excellent adhesiveness between a polarizer and an optical film and having good durability; and an image display device having the same.

### DESCRIPTION OF THE PREFERRED EMBODIMENTS

Hereinafter, the present invention will be described in detail.

Descriptions on the constitutional requirements which will be described later are made based on representative embodiments of the present invention in some cases, but it should not be construed that the present invention is limited to such embodiments.

Furthermore, in the present specification, a numerical value range expressed using “to” means a range that includes the preceding and succeeding numerical values of “to” as the lower limit value and the upper limit value, respectively.

In addition, in the present specification, only one kind of the substance corresponding to each component may be used alone or two or more kinds thereof may also be used in combination, for each component. Here, in a case where the two or more kinds of substances are used in combination for each component, the content of the component refers to a total content of the substances used in combination unless otherwise specified.

Moreover, in the present specification, “(meth)acrylate” is a notation representing “acrylate” or “methacrylate”, “(meth)acryl” is a notation representing “acryl” or “methacryl”, and “(meth)acryloyl” is a notation representing “acryloyl” or “methacryloyl”.

In addition, the bonding direction of a divalent group (for example, —O—CO—) as noted in the present specification is not particularly limited, and for example, in a case where in the bond of “L¹-L²-L³″, L² is —O—CO—, L² may be either *1-O—CO—*2 or *1-CO—O—*2, where *1 and *2 represent a bonding position to the L¹ side and a bonding position to the L³ side, respectively.

[Polarizing Plate]

The polarizing plate of an embodiment of the present invention is a polarizing plate having a polarizer, an adhesive layer, and an optical film exhibiting reverse wavelength dispersibility, adjacent to each other in this order.

In addition, the adhesive layer included in the polarizing plate of the embodiment of the present invention is a layer formed of an adhesive composition containing a polymerizable compound and a polymerization initiator.

Furthermore, the polarizing plate of the embodiment of the present invention is a polarizing plate that satisfies the following conditions 1 and 2.

Condition 1: A maximum absorption wavelength of the polymerization initiator is within ±70 nm of a minimum absorption wavelength of the optical film

Condition 2: A molar absorption coefficient of the polymerization initiator is 22,000 mol⁻¹Lcm⁻¹ or more

In the present invention, by configuring the polymerization initiator included in the adhesive composition forming the adhesive layer to satisfy the above-mentioned conditions 1 and 2, it is possible to manufacture a polarizing plate having an excellent adhesiveness between the polarizer and the optical film and having good durability.

A reason therefor is not specifically clear, but is presumed to be as follows by the present inventors.

First, it can be seen that in a case where an optical film not exhibiting reverse wavelength dispersibility is used, there is neither problem in the adhesiveness between the polarizer and the optical film, nor problem of deteriorated durability, as shown in Reference Example 1 which will be described later. Further, it can be seen that in a case where an optical film exhibiting reverse wavelength dispersibility is used and the polymerization initiator does not satisfy the above-mentioned condition 1 or condition 2, the adhesiveness between the polarizer and the optical film is deteriorated and the durability is also deteriorated, as shown in Comparative Examples 1 to 3 which will be described later. From these results, it is considered that by configuring the liquid crystal compound included in the optical film exhibiting the reverse wavelength dispersibility to absorb a part of light emitted from the optical film side at the time of curing the adhesive composition, the curing of the adhesive composition is inhibited from proceeding.

Therefore, in the present invention, it is considered that by configuring the polymerization initiator to satisfy the above-mentioned conditions 1 and 2, it is possible for the polymerization initiator to sufficiently function without being affected by light absorbed by the liquid crystal compound included in the optical film exhibiting reverse wavelength dispersibility, and therefore, the adhesiveness between the polarizer and the optical film is improved and the durability is also enhanced.

Hereinafter, a layer configuration of the polarizing plate of the embodiment of the present invention will be described in detail.

[Polarizer]

A polarizer contained in a polarizing plate of the embodiment of the present invention is not particularly limited as long as it is a member having a function of converting light into specific linearly polarized light, and an absorptive type polarizer and a reflective type polarizer, which are known in the related art, can be used.

An iodine-based polarizer, a dye-based polarizer using a dichroic dye, a polyene-based polarizer, or the like is used as the absorptive type polarizer. The iodine-based polarizer and the dye-based polarizer are classified into a coating type polarizer and a stretching type polarizer, any of which can be applied, but a polarizer which is manufactured by allowing polyvinyl alcohol to adsorb iodine or a dichroic dye and performing stretching is preferable.

In addition, examples of a method of obtaining a polarizer by carrying out stretching and dying in a state of a laminated film in which a polyvinyl alcohol layer is formed on a base material include the methods disclosed in JP5048120B, JP5143918B, JP4691205B, JP4751481B, and JP4751486B, and known technologies relating to these polarizers can also be preferably used.

A polarizer in which thin films having different birefringence are laminated, a wire grid-type polarizer, a polarizer having a combination of a cholesteric liquid crystal having a selective reflection range, and a ¼ wavelength plate, or the like is used as the reflective type polarizer.

Among those, a polarizer including a polyvinyl alcohol-based resin (a polymer including —CH₂—CHOH— as a repeating unit, in particular, at least one selected from the group consisting of a polyvinyl alcohol and an ethylene-vinyl alcohol copolymer) is preferable from the viewpoint that it has more excellent adhesiveness.

In the present invention, the thickness of the polarizer is not particularly limited, but is preferably 3 μm to 60 μm, more preferably 3 μm to 30 μm, and still more preferably 3 μm to 10 μm.

[Optical Film]

The optical film included in the polarizing plate of the embodiment of the present invention is an optical film exhibiting reverse wavelength dispersibility.

Here, the optical film exhibiting reverse wavelength dispersibility is an optically anisotropic layer having an in-plane retardation value Re(450) measured at a wavelength of 450 nm, an in-plane retardation value Re(550) measured at a wavelength of 550 nm, and an in-plane retardation value Re(650) measured at a wavelength of 650 nm, which satisfy a relationship of Re(450)<Re(550)<Re(650).

In addition, the value of the in-plane retardation refers to a value measured with light at the measurement wavelength using AxoScan OPMF-1 (manufactured by Opto Science, Inc.).

Specifically, by inputting an average refractive index ((Nx+Ny+Nz)/3) and a film thickness (d (μm)) to AxoScan OPMF-1, it is possible to calculate:
Slow axis direction (°)
Re(λ)=R0(λ)
Rth(λ)=((nx+ny)/2−nz)×d.

In addition, R0(λ) is expressed in a numerical value calculated with AxoScan OPMF-1, but means Re(λ).

<Optically Anisotropic Layer>

In the present invention, it is preferable that the optical film has one or two or more optically anisotropic layers formed of a polymerizable liquid crystal composition containing a polymerizable liquid crystal compound.

(Polymerizable Liquid Crystal Compound)

The polymerizable liquid crystal compound is preferably a compound having a linking group represented by any of Formulae (Ar-1) to (Ar-7) for a reason that the effects of the present invention of an excellent adhesiveness between the polarizer and the optical film and good durability are apparent.

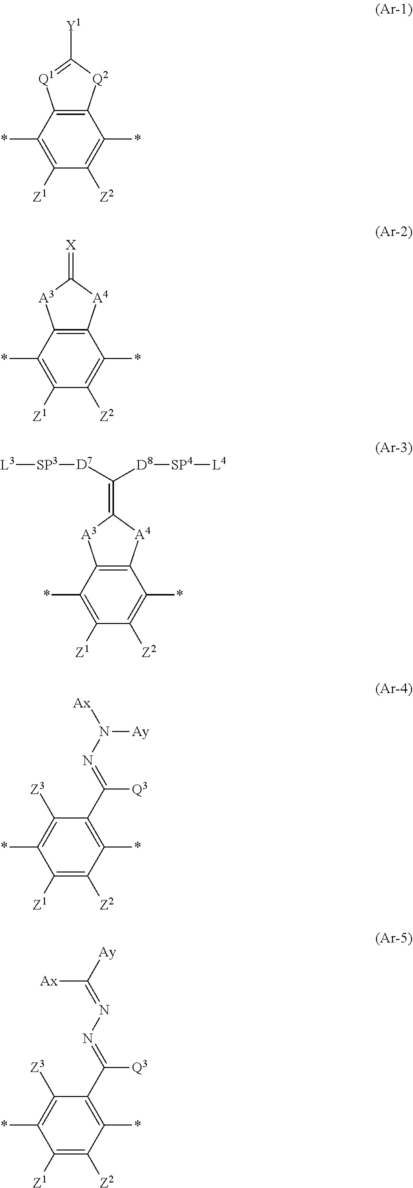

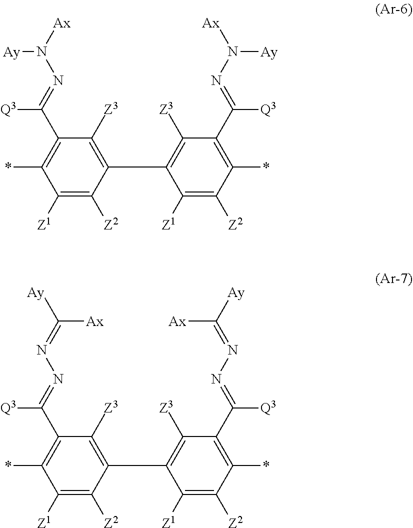

In Formulae (Ar-1) to (Ar-7), * represents a bonding position, that is, a bonding position to a portion other than the linking group included in the polymerizable liquid crystal compound.

In addition, in Formula (Ar-1), Q¹ represents N or CH, Q² represents —S—, —O—, or —N(R⁶)—, R⁶ represents a hydrogen atom or an alkyl group having 1 to 6 carbon atoms, Y¹ represents an aromatic hydrocarbon group having 6 to 12 carbon atoms, which may have a substituent, an aromatic heterocyclic group having 3 to 12 carbon atoms, which may have a substituent, or an alicyclic hydrocarbon group having 6 to 20 carbon atoms, which may have a substituent, and one or more of —CH₂-'s constituting the alicyclic hydrocarbon group may be substituted with —O—, —S—, or —NH—.

Here, specific examples of the alkyl group having 1 to 6 carbon atoms, represented by R⁶, include a methyl group, an ethyl group, a propyl group, an isopropyl group, an n-butyl group, an isobutyl group, a sec-butyl group, a tert-butyl group, an n-pentyl group, and an n-hexyl group.

In addition, examples of the aromatic hydrocarbon group having 6 to 12 carbon atoms, represented by Y′, include aryl groups such as a phenyl group, a 2,6-diethylphenyl group, and a naphthyl group.

Examples of the aromatic heterocyclic group having 3 to 12 carbon atoms, represented by Y′, include heteroaryl groups such as a thienyl group, a thiazolyl group, a furyl group, and a pyridyl group.

Examples of the alicyclic hydrocarbon group having 6 to 20 carbon atoms, represented by V, include a cyclohexylene group, a cyclopentylene group, a norbornene group, and an adamantylene group.

Examples of a substituent which may be contained in Y¹ include an alkyl group, an alkoxy group, an alkylcarbonyl group, an alkoxycarbonyl group, an alkylcarbonyloxy group, an alkylamino group, a dialkylamino group, an alkylamide group, an alkenyl group, an alkynyl group, a halogen atom, a cyano group, a nitro group, an alkylthiol group, and an N-alkylcarbamate group, and among these, the alkyl group, the alkoxy group, the alkoxycarbonyl group, the alkylcarbonyloxy group, or the halogen atom is preferable.

As the alkyl group, a linear, branched, or cyclic alkyl group having 1 to 18 carbon atoms is preferable, an alkyl group having 1 to 8 carbon atoms (for example, a methyl group, an ethyl group, a propyl group, an isopropyl group, an n-butyl group, an isobutyl group, a sec-butyl group, a t-butyl group, and a cyclohexyl group) is more preferable, an alkyl group having 1 to 4 carbon atoms is still more preferable, and the methyl group or the ethyl group is particularly preferable.

As the alkoxy group, an alkoxy group having 1 to 18 carbon atoms is preferable, an alkoxy group having 1 to 8 carbon atoms (for example, a methoxy group, an ethoxy group, an n-butoxy group, and a methoxyethoxy group) is more preferable, an alkoxy group having 1 to 4 carbon atoms is still more preferable, and the methoxy group or the ethoxy group is particularly preferable.

Examples of the alkoxycarbonyl group include a group in which an oxycarbonyl group (—O—CO— group) is bonded to the alkyl group exemplified above, and among these, the alkoxycarbonyl group is preferably a methoxycarbonyl group, an ethoxycarbonyl group, an n-propoxycarbonyl group, or an isopropoxycarbonyl group, and more preferably the methoxycarbonyl group.

Examples of the alkylcarbonyloxy group include a group in which a carbonyloxy group (—CO—O— group) is bonded to the alkyl group exemplified above, and among these, the alkylcarbonyloxy group is preferably a methylcarbonyloxy group, an ethylcarbonyloxy group, an n-propylcarbonyloxy group, or an isopropylcarbonyloxy group, and more preferably the methylcarbonyloxy group.

Examples of the halogen atom include a fluorine atom, a chlorine atom, a bromine atom, and an iodine atom, and among these, the fluorine atom or the chlorine atom is preferable.

In addition, in Formulae (Ar-1) to (Ar-7), Z¹, Z², and Z³ each independently represent a hydrogen atom, a monovalent aliphatic hydrocarbon group having 1 to 20 carbon atoms, a monovalent alicyclic hydrocarbon group having 3 to 20 carbon atoms, a monovalent aromatic hydrocarbon group having 6 to 20 carbon atoms, a monovalent aromatic heterocyclic group having 6 to 20 carbon atoms, a halogen atom, a cyano group, a nitro group, —OR⁷, —NR⁸R⁹, —SR¹⁰, —COOR¹¹, or —COR¹², where R⁷ to R¹² each independently represent a hydrogen atom or an alkyl group having 1 to 6 carbon atoms, and Z¹ and Z² may be bonded to each other to form an aromatic ring.

Here, as the monovalent aliphatic hydrocarbon group having 1 to 20 carbon atoms, an alkyl group having 1 to 15 carbon atoms is preferable, an alkyl group having 1 to 8 carbon atoms is more preferable, and specifically a methyl group, an ethyl group, an isopropyl group, a tert-pentyl group (1,1-dimethylpropyl group), a tert-butyl group, or a 1,1-dimethyl-3,3-dimethylbutyl group is still more preferable, and the methyl group, the ethyl group, or the tert-butyl group is particularly preferable.

Examples of the monovalent alicyclic hydrocarbon group having 3 to 20 carbon atoms include monocyclic saturated hydrocarbon groups such as a cyclopropyl group, a cyclobutyl group, a cyclopentyl group, a cyclohexyl group, a cycloheptyl group, a cyclooctyl group, a cyclodecyl group, a methylcyclohexyl group, and an ethylcyclohexyl group; monocyclic unsaturated hydrocarbon groups such as a cyclobutenyl group, a cyclopentenyl group, a cyclohexenyl group, a cycloheptenyl group, a cyclooctenyl group, a cyclodecenyl group, a cyclopentadienyl group, a cyclohexadienyl group, a cyclooctadienyl group, and a cyclodecadiene; and polycyclic saturated hydrocarbon groups such as a bicyclo[2.2.1]heptyl group, a bicyclo[2.2.2]octyl group, a tricyclo[5.2.1.0^{2,6}]decyl group, a tricyclo[3.3.1.1^{3,7}]decyl group, a tetracyclo[6.2.1.1^{3,6}.0^{2,7}]dodecyl group, and an adamantyl group.

Specific examples of the monovalent aromatic hydrocarbon group having 6 to 20 carbon atoms include a phenyl group, a 2,6-diethylphenyl group, a naphthyl group, and a biphenyl group, and an aryl group having 6 to 12 carbon atoms (particularly a phenyl group) is preferable.

Specific examples of the monovalent aromatic heterocyclic group having 6 to 20 carbon atoms include a 4-pyridyl group, a 2-furyl group, a 2-thienyl group, a 2-pyrimidinyl group, and a 2-benzothiazolyl group.

Examples of the halogen atom include a fluorine atom, a chlorine atom, a bromine atom, and an iodine atom, and among these, the fluorine atom, the chlorine atom, or the bromine atom is preferable.

On the other hand, specific examples of the alkyl group having 1 to 6 carbon atoms, represented by each of R⁷ to R¹⁰, include a methyl group, an ethyl group, a propyl group, an isopropyl group, an n-butyl group, an isobutyl group, a sec-butyl group, a tert-butyl group, an n-pentyl group, and an n-hexyl group.

In addition, as described above, Z¹ and Z² may be bonded to each other to form an aromatic ring, and examples of the structure in a case where Z¹ and Z² in Formula (Ar-1) are bonded to each other form an aromatic ring include a group represented by Formula (Ar-1a). Furthermore, in Formula (Ar-1a), * represents a bonding position, and examples of Q¹, Q², and Y¹ include the same ones as those described in Formula (Ar-1).

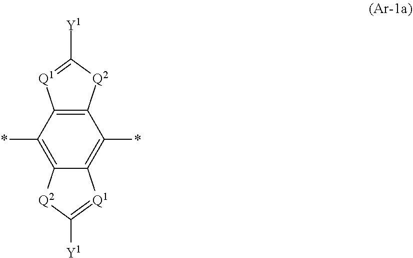

In addition, in Formulae (Ar-2) and (Ar-3), A3 and A4 each independently represent a group selected from the group consisting of —O—, —N(R¹³)—, —S—, and —CO—, where R¹³ represents a hydrogen atom or a substituent.

Examples of the substituent represented by R¹³ include the same ones as the substituents which may be contained in Y¹ in Formula (Ar-1).

In addition, in Formula (Ar-2), X represents a hydrogen atom or a non-metal atom of Groups XIV to XVI, to which a substituent may be bonded.

Examples of the non-metal atom of Groups XIV to XVI represented by X include an oxygen atom, a sulfur atom, a nitrogen atom to which a hydrogen atom or a substituent is bonded [═N—R^{N1}, R^{N1} represents a hydrogen atom or a substituent], and a carbon atom to which a hydrogen atom or a substituent is bonded [C—(R^{C1})₂, R^{C1} represents a hydrogen atom or a substituent].

Examples of the substituent include an alkyl group, an alkoxy group, an alkyl-substituted alkoxy group, a cyclic alkyl group, an aryl group (for example, a phenyl group and a naphthyl group), a cyano group, an amino group, a nitro group, an alkylcarbonyl group, a sulfo group, and a hydroxyl group.

In addition, in Formula (Ar-3), D⁷ and D⁸ each independently represent a single bond; or —CO—, —O—, —S—, —C(═S)—, —CR¹R²—, —CR³═CR⁴—, —NRf—, or a divalent linking group consisting of a combination of two or more of these groups, where R¹ to R⁵ each independently represent a hydrogen atom, a fluorine atom, or an alkyl group having 1 to 12 carbon atoms.

Here, examples of the divalent linking group represented by one aspect of D⁷ and D⁸ include —CO—, —O—, —CO—O—, —C(═S)O—, —CR¹R²—, —CR¹R²—CR¹R²—, —O—CR¹R²—, —CR¹R²—O—CR¹R²—, —CO—O—CR¹R²—, —O—CO—CR¹R²—, —CR¹R²—O—CO—CR¹R²—, —CR¹R²—CO—O—CR¹R²—, —NR⁵—CR¹R²—, and —CO—NR⁵—. R¹, R², and R⁵ each independently represent a hydrogen atom, a fluorine atom, or an alkyl group having 1 to 12 carbon atoms.

Among these, any of —CO—, —O—, and —CO—O— is preferable.

Moreover, in Formula (Ar-3), SP³ and SP⁴ each independently represent a single bond, a linear or branched alkylene group having 1 to 12 carbon atoms, or a divalent linking group in which one or more of —CH₂-'s constituting the linear or branched alkylene group having 1 to 12 carbon atoms are substituted with —O—, —S—, —NH—, —N(Q)-, or —CO—, where Q represents a substituent. Examples of the substituent include the same ones as the substituents which may be contained in Y¹ in Formula (Ar-1).

Here, suitable examples of the linear or branched alkylene group having 1 to 12 carbon atoms, represented by one aspect of SP³ and SP⁴, include a methylene group, an ethylene group, a propylene group, a butylene group, a pentylene group, a hexylene group, a methylhexylene group, and a heptylene group. Incidentally, SP¹ and SP² may be a divalent linking group in which one or more of —CH₂-'s constituting the linear or branched alkylene group having 1 to 12 carbon atoms are substituted with —O—, —S—, —NH—, —N(Q)-, or —CO—, as described above, and examples of the substituent represented by Q include the same ones as the substituents which may be contained in Y¹ in Formula (Ar-1).

Moreover, in Formula (Ar-3), L³ and L⁴ each independently represent a monovalent organic group.

Examples of the monovalent organic group represented by each of L³ and L⁴ include an alkyl group, an aryl group, and a heteroaryl group.

The alkyl group may be linear, branched, or cyclic, but is preferably linear. The number of carbon atoms of the alkyl group is preferably 1 to 30, more preferably 1 to 20, and still more preferably 1 to 10.

Further, the aryl group may be a monocycle or a polycycle, but is preferably the monocycle. The number of carbon atoms of the aryl group is preferably 6 to 25, and more preferably 6 to 10.

In addition, the heteroaryl group may be a monocycle or a polycycle. The number of heteroatoms constituting the heteroaryl group is preferably 1 to 3. The heteroatom constituting the heteroaryl group is preferably a nitrogen atom, a sulfur atom, or an oxygen atom. The number of carbon atoms of the heteroaryl group is preferably 6 to 18, and more preferably 6 to 12.

In addition, the alkyl group, the aryl group, and the heteroaryl group may be unsubstituted or have a substituent. Examples of the substituent include the same ones as the substituents which may be contained in Y¹ in General Formula (Ar-1).

Moreover, in Formulae (Ar-4) to (Ar-7), Ax represents an organic group having 2 to 30 carbon atoms, which has at least one aromatic ring selected from the group consisting of an aromatic hydrocarbon ring and an aromatic heterocyclic ring.

Furthermore, in Formulae (Ar-4) to (Ar-7), Ay represents a hydrogen atom, an alkyl group having 1 to 12 carbon atoms, which may have a substituent, or an organic group having 2 to 30 carbon atoms, which has at least one aromatic ring selected from the group consisting of an aromatic hydrocarbon ring and an aromatic heterocyclic ring.

Here, the aromatic ring in each of Ax and Ay may have a substituent, and Ax and Ay may be bonded to each other to form a ring.

In addition, Q³ represents a hydrogen atom or an alkyl group having 1 to 6 carbon atoms, which may have a substituent.

Examples of each of Ax and Ay include the ones described in paragraphs [0039] to [0095] of WO2014/010325A.

In addition, specific examples of the alkyl group having 1 to 20 carbon atoms, represented by Q³, include a methyl group, an ethyl group, a propyl group, an isopropyl group, an n-butyl group, an isobutyl group, a sec-butyl group, a tert-butyl group, an n-pentyl group, and an n-hexyl group, and examples of the substituent include the same ones as the substituents which may be contained in Y¹ in Formula (Ar-1).

In the present invention, the polymerizable liquid crystal compound is preferably a compound represented by Formula (I) from the viewpoint that the retardation of the formed optically anisotropic layer is satisfactorily expressed. Furthermore, in Formula (I), Ar represents any of aromatic rings selected from the group consisting of the groups represented by Formulae (Ar-1) to (Ar-7) mentioned above. It should be noted that in a case where q1 in Formula (I) is 2, a plurality of Ar's may be the same as or different from each other.

L¹-SP¹-D⁵-(A¹)ₐ₁-D³-(G¹)_{g1}-D¹-[Ar-D²]_{q1}-(G²)_{g2}-D⁴-(A²)ₐ₂-D6-SP²-L² (1)

In Formula (I), a1, a2, g1, and g2 each independently represent 0 or 1. It should be noted that at least one of a1 or g1 represents 1, and at least one of a2 or g2 represents 1.

In addition, in Formula (I), q1 represents 1 or 2.

Moreover, in Formula (I), D¹, D², D³, D⁴, D⁵, and D⁶ each independently represent a single bond; —CO—, —O—, —S—, —C(═S)—, —CR¹R²—, —CR³═CR⁴—, —NR—, or a divalent linking group consisting of a combination of two or more of these groups, and R¹ to R⁵ each independently represent a hydrogen atom, a fluorine atom, or an alkyl group having 1 to 12 carbon atoms. It should be noted that in a case where q1 is 2, a plurality of D²'s may be the same as or different from each other.

In addition, in Formula (I), G¹ and G² each independently represent an aromatic ring having 6 to 20 carbon atoms, which may have a substituent, or a divalent alicyclic hydrocarbon group having 5 to 20 carbon atoms, which may have a substituent, and one or more of —CH₂-'s constituting the alicyclic hydrocarbon group may be substituted with —O—, —S—, or —NH—.

In addition, in Formula (I), A¹ and A² each independently represent an aromatic ring having 6 to 20 carbon atoms, which may have a substituent, or a divalent alicyclic hydrocarbon group having 5 to 20 carbon atoms, which may have a substituent, and one or more of —CH₂-'s constituting the alicyclic hydrocarbon group may be substituted with —O—, —S—, or —NH—. Furthermore, in Formula (I), SP¹ and SP² each independently represent a single bond, a linear or branched alkylene group having 1 to 12 carbon atoms, or a divalent linking group in which one or more of —CH₂-'s constituting the linear or branched alkylene group having 1 to 12 carbon atoms are substituted with —O—, —S—, —NH—, —N(Q)-, or —CO—, where Q represents a substituent.

In addition, in Formula (I), L¹ and L² each independently represent a monovalent organic group, and at least one of L¹ or L² represents a polymerizable group. It should be noted that in a case where Ar is an aromatic ring represented by Formula (Ar-3), at least one of L¹ or L², or L³ or L⁴ in Formula (Ar-3) represents a polymerizable group, and

In Formula (I), it is preferable that any of a1, a2, g1, and g2 is 1 for a reason that the polymerizable liquid crystal composition is more likely to exhibit a liquid crystal state of a smectic phase.

In addition, it is preferable that both of a1 and a2 are 0 and both of g1 and g2 are 1 for a reason that the contrast of an image display device thus manufactured is better.

In Formula (I), q1 is preferably 1.

In Formula (I), examples of the divalent linking group represented by one aspect of D¹, D², D³, D⁴, D⁵, and D⁶ include the same ones as those described in D⁷ and D⁸ in Formula (Ar-3).

Among these, any of —CO—, —O—, and —CO—O— is preferable.

In Formula (I), examples of the aromatic ring having 6 to 20 carbon atoms, shown by one aspect of G¹ and G², include an aromatic hydrocarbon ring such as a benzene ring, a naphthalene ring, an anthracene ring, and a phenanthroline ring; and an aromatic heterocyclic ring such as a furan ring, a pyrrole ring, a thiophene ring, a pyridine ring, a thiazole ring, and a benzothiazole ring. Among those, the benzene ring (for example, a 1,4-phenyl group) is preferable.

In Formula (I), the divalent alicyclic hydrocarbon group having 5 to 20 carbon atoms, shown by one aspect of G¹ and G², is preferably a 5- or 6-membered ring. In addition, the alicyclic hydrocarbon group may be saturated or unsaturated, but is preferably a saturated alicyclic hydrocarbon group. With regard to the divalent alicyclic hydrocarbon group represented by each of G¹ and G², reference can be made to, for example, the description in paragraph [0078] of JP2012-21068A, the contents of which are hereby incorporated by reference.

In the present invention, G¹ and G² in Formula (I) are each preferably a cycloalkane ring for a reason that the contrast of an image display device thus manufactured is better. Specific examples of the cycloalkane ring include a cyclohexane ring, a cyclopeptane ring, a cyclooctane ring, a cyclododecane ring, and a cyclodocosane ring.

Among those, the cyclohexane ring is preferable, a 1,4-cyclohexylene group is more preferable, and a trans-1,4-cyclohexylene group is still more preferable.

Moreover, in Formula (I), examples of the substituent which may be contained in the aromatic ring having 6 to 20 carbon atoms or the divalent alicyclic hydrocarbon group having 5 to 20 carbon atoms in G¹ and G² include the same ones as the substituents which may be contained in Y¹ in Formula (Ar-1).

In Formula (I), examples of the aromatic ring having 6 to 20 or more carbon atoms, shown by one aspect of A¹ and A², include the same ones as those described in G¹ and G² in Formula (I).

In addition, in Formula (I), examples of the divalent alicyclic hydrocarbon group having 5 to 20 carbon atoms, represented by one aspect of A¹ and A², include the same ones as those described in G¹ and G² in Formula (I).

Moreover, examples of the substituent which may be contained in the aromatic ring having 6 to 20 carbon atoms or the divalent alicyclic hydrocarbon group having 5 to 20 carbon atoms in A¹ and A² include the same ones as the substituents which may be contained in Y¹ in Formula (Ar-1).

In Formula (I), examples of the linear or branched alkylene group having 1 to 12 carbon atoms, represented by one aspect of SP¹ and SP², include the same ones as those described in SP³ and SP⁴ in Formula (Ar-3).

In Formula (I), examples of the monovalent organic group represented by each of L¹ and L² include the same ones as those described in L³ and L⁴ in Formula (Ar-3).

In Formula (I), the polymerizable group represented by at least one of L¹ or L² is not particularly limited, but is preferably a polymerizable group which is radically polymerizable or cationically polymerizable.

A known radically polymerizable group can be used as the radically polymerizable group, and suitable examples thereof include an acryloyloxy group or a methacryloyloxy group. In this case, it is known that the acryloyloxy group generally has a high polymerization rate, and from the viewpoint of improvement of productivity, the acryloyloxy group is preferable but the methacryloyloxy group can also be used as the polymerizable group.

A known cationically polymerizable group can be used as the cationically polymerizable group, and specific examples thereof include an alicyclic ether group, a cyclic acetal group, a cyclic lactone group, a cyclic thioether group, a spiroorthoester group, and a vinyloxy group. Among those, the alicyclic ether group or the vinyloxy group is suitable, and an epoxy group, an oxetanyl group, or the vinyloxy group is particularly preferable.

Particularly preferred examples of the polymerizable group include a polymerizable group represented by any of Formulae (P-1) to (P-20).

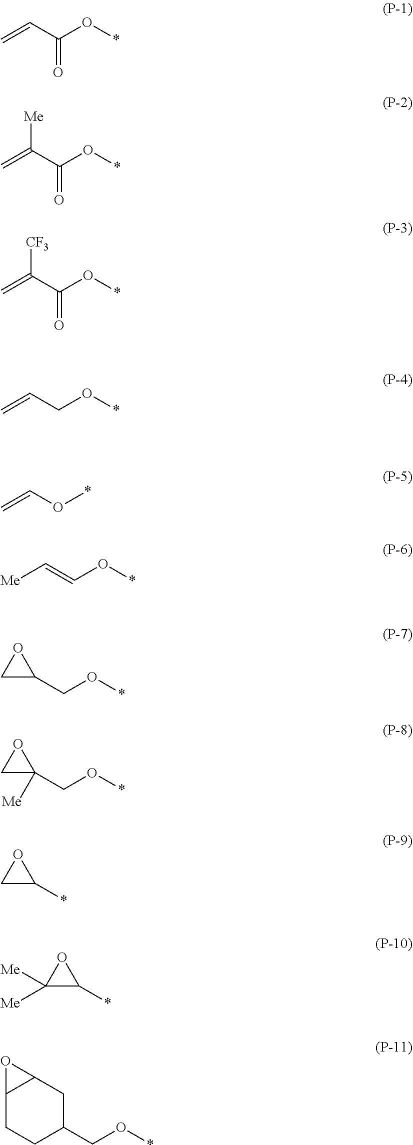

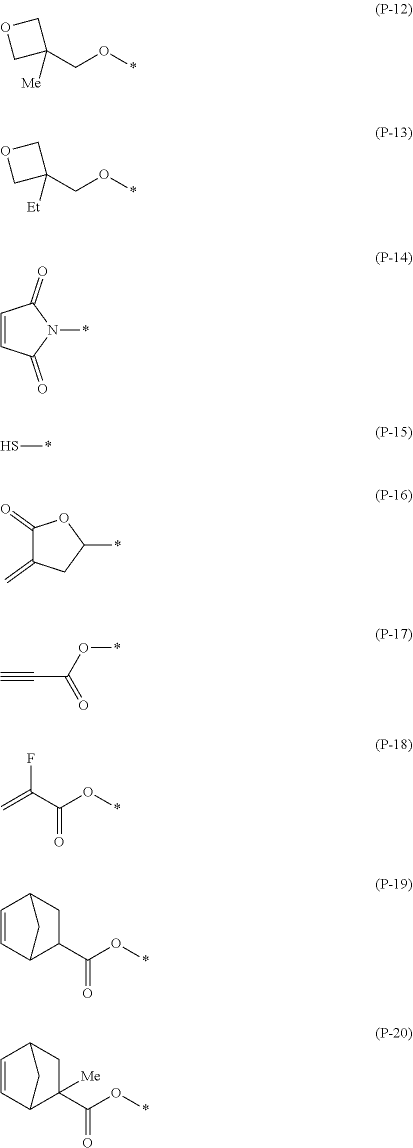

In Formula (I), for a reason that the durability of the polarizing plate is further improved, any of L¹ and L² in Formula (I) is preferably a polymerizable group, and more preferably an acryloyloxy group or a methacryloyloxy group.

Examples of the compound represented by Formula (I) include the compounds represented by General Formula (I) described in JP2010-084032A (in particular, the compounds described in paragraph Nos. [0067] to [0073]), the compound represented by General Formula (II) described in JP2016-053709A (in particular, the compounds described in paragraph Nos. (II), and the compounds represented by General Formula (I) described in JP2016-081035A (in particular, the compounds described in paragraph Nos. [0043] to [0055]).

Moreover, suitable examples of the compound represented by Formula (I) include compounds represented by Formulae (1) to (22), and specific examples thereof include the compounds having side chain structures shown in Tables 1 to 3 below as K (side chain structure) in Formulae (1) to (22).

Furthermore, in Tables 1 to 3 below, “*” shown in the side chain structure of K represents a bonding position to an aromatic ring.

In addition, in the side chain structures shown in 2-2 in Table 2 below and 3-2 in Table 3 below, a group adjacent to each of the acryloyloxy group and the methacryloyl group represents a propylene group (a group in which a methyl group is substituted with an ethylene group), and represents a mixture of regioisomers in which the positions of the methyl groups are different.

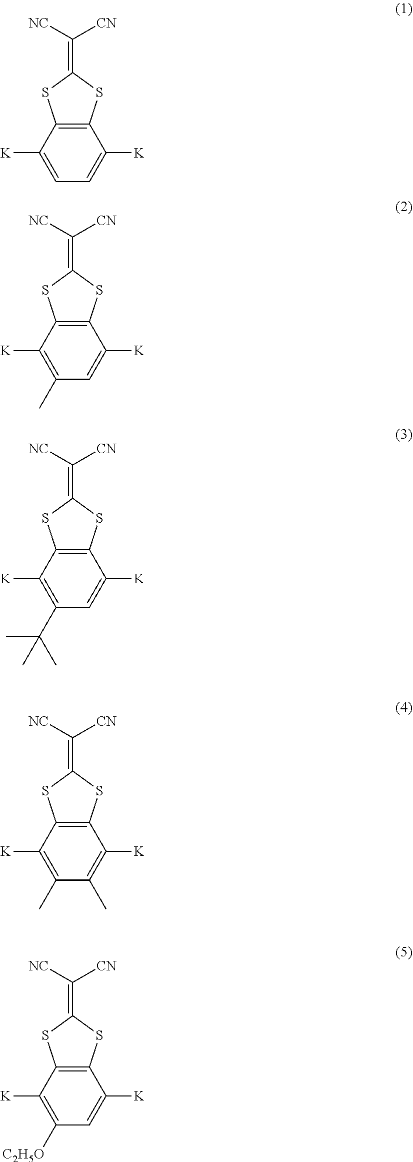

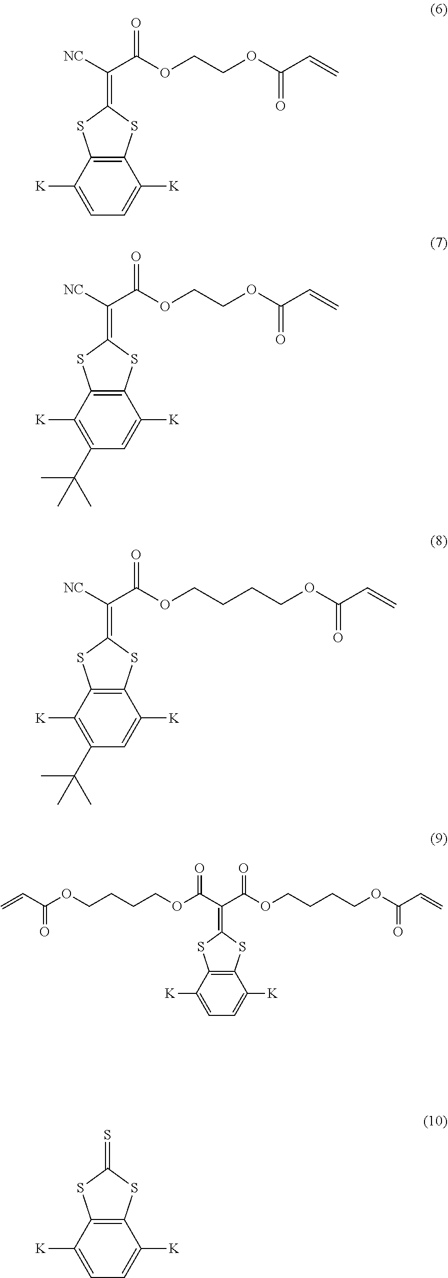

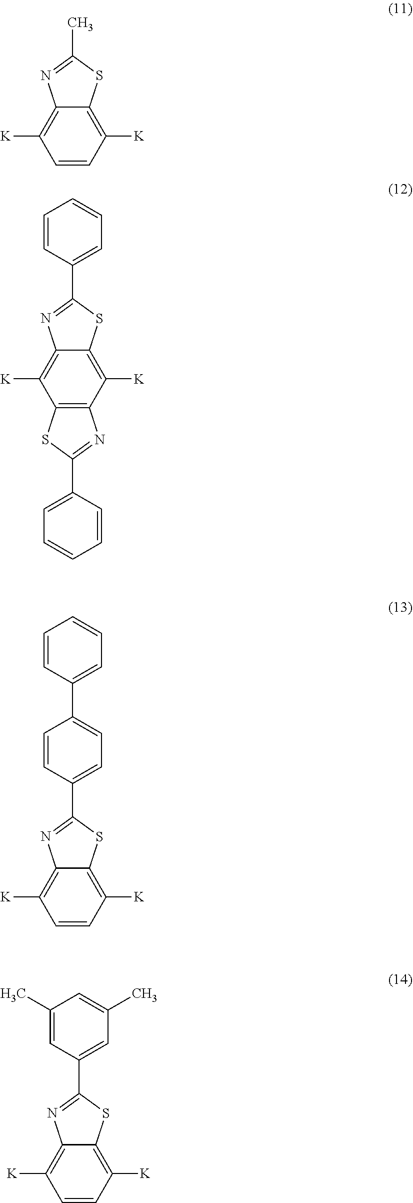

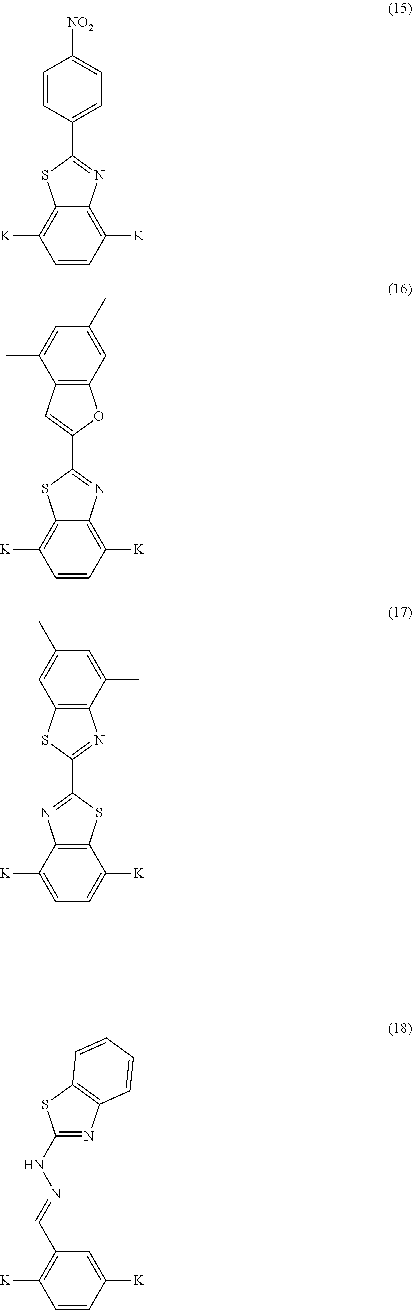

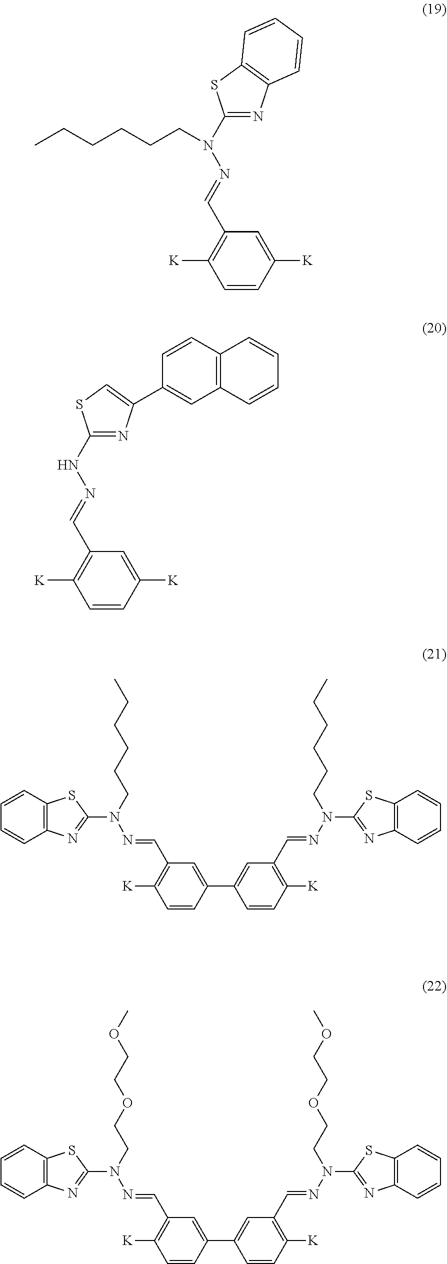

TABLE 1

| | K (Side chain structure) |
|---|---|
| 1-1 | 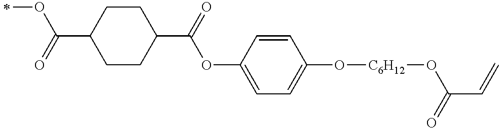 |
| 1-2 | 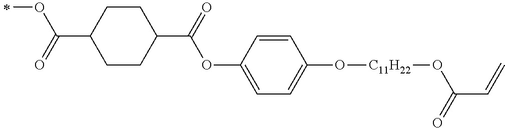 |
| 1-3 | 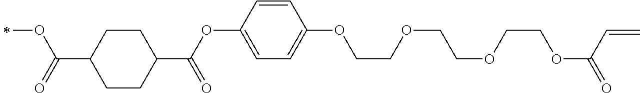 |
| 1-4 | 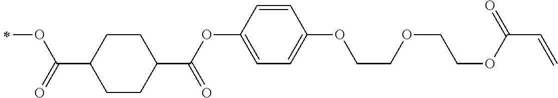 |
| 1-5 | 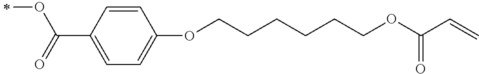 |
| 1-6 | 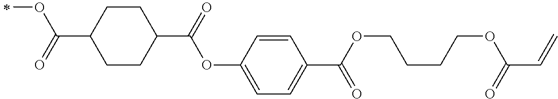 |

TABLE 2

| | K (Side chain structure) |
|---|---|
| 2-1 | 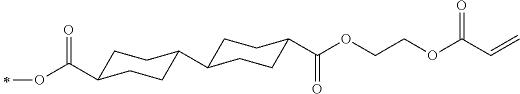 |
| 2-2 | 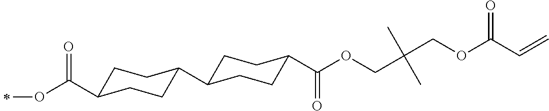 |
| 2-3 | 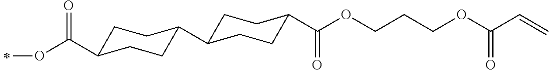 |
| 2-4 | 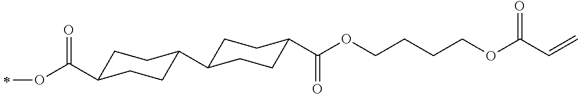 |
| 2-5 | 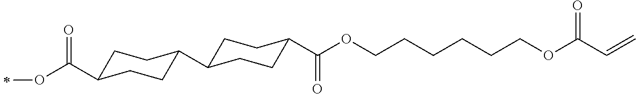 |
| 2-6 | 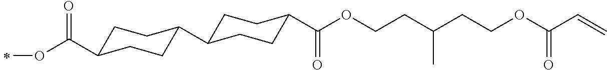 |
| 2-7 | 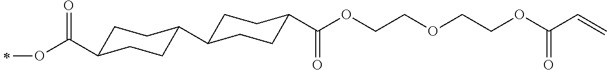 |
| 2-8 | 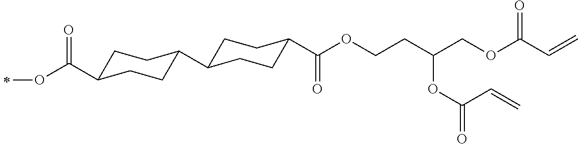 |
| 2-9 | 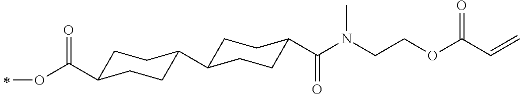 |
| 2-10 | 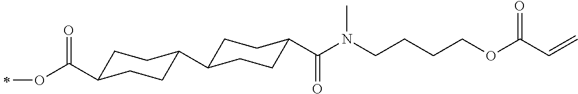 |
| 2-11 | 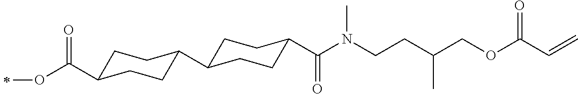 |
| 2-12 | 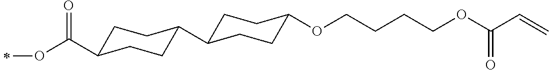 |
| 2-13 | 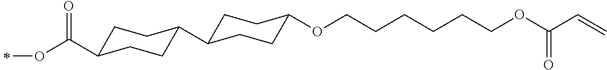 |
| 2-14 | 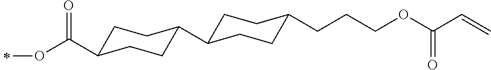 |

| | K (Side chain structure) |
|---|---|
| 3-1 | 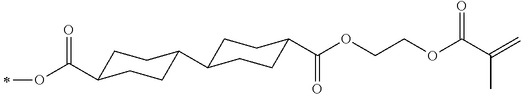 |
| 3-2 | 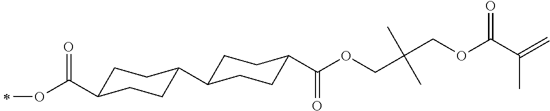 |
| 3-3 | 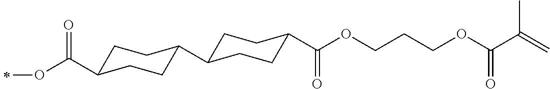 |
| 3-4 | 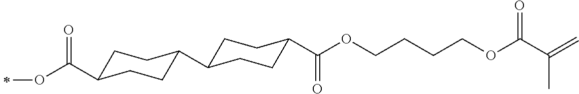 |
| 3-5 | 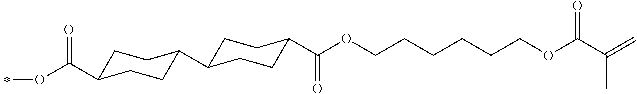 |
| 3-6 | 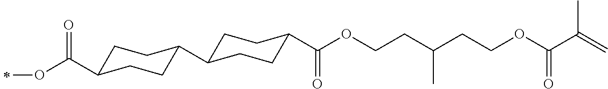 |
| 3-7 | 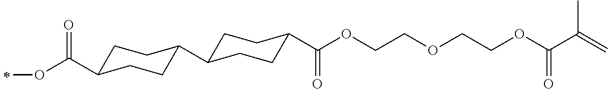 |
| 3-8 | 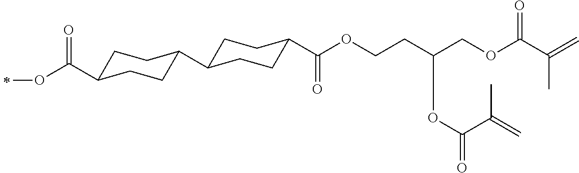 |
| 3-9 | 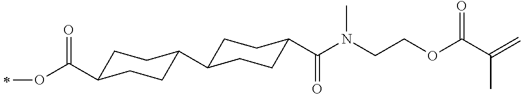 |
| 3-10 | 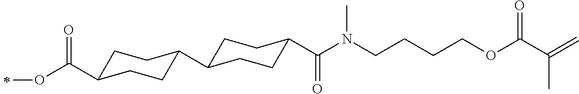 |
| 3-11 | 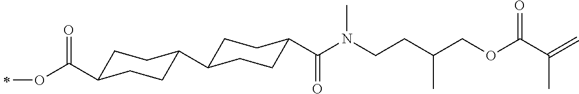 |
| 3-12 | 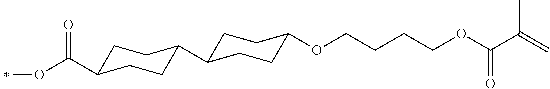 |
| 3-13 | 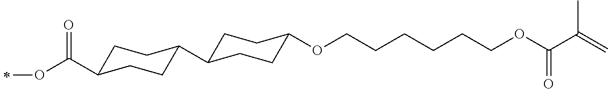 |
| 3-14 | 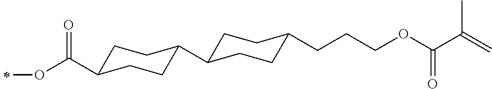 |

In the present invention, it is preferable that the above-mentioned polymerizable liquid crystal compound, in particular, the above-mentioned compound represented by Formula (I) is a compound exhibiting a liquid crystal state of a smectic phase for a reason that the contrast of an image display device thus manufactured is better.

(Polymerization Initiator)

The polymerizable liquid crystal composition preferably contains a polymerization initiator in addition to the above-mentioned polymerizable liquid crystal compound.

The polymerization initiator to be used is preferably a photopolymerization initiator capable of initiating a polymerization reaction upon irradiation with ultraviolet rays.

Examples of the photopolymerization initiator include a-carbonyl compounds (described in each of the specifications of U.S. Pat. Nos. 2,367,661A and 2,367,670A), acyloin ethers (described in the specification of U.S. Pat. No. 2,448,828A), a-hydrocarbon-substituted aromatic acyloin compounds (described in the specification of U.S. Pat. No. 2,722,512A), multinuclear quinone compounds (described in each of the specifications of U.S. Pat. Nos. 3,046,127A and 2,951,758A), combinations of a triarylimidazole dimer and a p-aminophenyl ketone (described in the specification of U.S. Pat. No. 3,549,367A), acridine and phenazine compounds (described in JP1985-105667A (JP-S60-105667A) and the specification of U.S. Pat. No. 4,239,850A), oxadiazole compounds (described in the specification of U.S. Pat. No. 4,212,970A), and acyl phosphine oxide compounds (described in JP1988-40799B (JP-S63-40799B), JP1993-29234B (JP-H05-29234B), JP1998-95788A (JP-H10-95788A), and JP1998-29997A(JP-H10-29997A)).

In addition, in the present invention, it is also preferable that the polymerization initiator is an oxime-type polymerization initiator, and specific examples of the polymerization initiator include the initiators described in paragraphs [0049] to [0052] of WO2017/170443A.

(Solvent)

It is preferable that the polymerizable liquid crystal composition contains a solvent in addition to the above-mentioned polymerizable liquid crystal compound from the viewpoints of workability for forming an optically anisotropic layer, and the like.

Specific examples of the solvent include ketones (for example, acetone, 2-butanone, methyl isobutyl ketone, cyclohexanone, and cyclopentanone), ethers (for example, dioxane and tetrahydrofuran), aliphatic hydrocarbons (for example, hexane), alicyclic hydrocarbons (for example, cyclohexane), aromatic hydrocarbons (for example, toluene, xylene, and trimethylbenzene), halogenated carbons (for example, dichloromethane, dichloroethane, dichlorobenzene, and chlorotoluene), esters (for example, methyl acetate, ethyl acetate, and butyl acetate), water, alcohols (for example, ethanol, isopropanol, butanol, and cyclohexanol), cellosolves (for example, methyl cellosolve and ethyl cellosolve), cellosolve acetates, sulfoxides (for example, dimethyl sulfoxide), and amides (for example, dimethylformamide and dimethylacetamide), and these may be used singly or in combination of two or more kinds thereof.

(Leveling Agent)

It is preferable that the polymerizable liquid crystal composition contains a leveling agent in addition to the above-mentioned polymerizable liquid crystal compound from the viewpoint that a surface of the optically anisotropic layer is maintained smooth and the alignment is easily controlled.

Such a leveling agent is preferably a fluorine-based leveling agent or a silicon-based leveling agent for a reason that it has a high leveling effect on the addition amount, and the leveling agent is more preferably a fluorine-based leveling agent from the viewpoint that it is less likely to cause bleeding (bloom or bleed).

Specific examples of the leveling agent include the compounds described in paragraphs [0079] to [0102] of JP2007-069471A, the compound represented by General Formula (I) described in JP2013-047204A (in particular, the compounds described in paragraphs [0020] to [0032], the compound represented by General Formula (I) described in JP2012-211306A (in particular, the compounds described in paragraphs [0022] to [0029]), the liquid crystal alignment accelerator represented by General Formula (I) described in JP2002-129162A (in particular, the compounds described in paragraphs [0076] to [0078] and [0082] to [0084]), and the compounds represented by General Formulae (I), (II), and (III) described in JP2005-099248A (in particular, the compounds described in paragraphs [0092] to [0096]). In addition, the leveling agent may also function as an alignment control agent which will be described later.

(Alignment Control Agent)

The polymerizable liquid crystal composition can contain, as necessary, an alignment control agent in addition to the above-mentioned polymerizable liquid crystal compound.

With the alignment control agent, various alignment states such as homeotropic alignment (vertical alignment), tilt alignment, hybrid alignment, and cholesteric alignment can be formed, in addition to the homogeneous alignment, and specific alignment states can be controlled and achieved more uniformly and more accurately.

As an alignment control agent which accelerates the homogeneous alignment, for example, a low-molecular-weight alignment control agent or a high-molecular-weight alignment control agent can be used.

With regard to the low-molecular-weight alignment control agent, reference can be made to the description in, for example, paragraphs [0009] to [0083] of JP2002-20363A, paragraphs [0111] to [0120] of JP2006-106662A, and paragraphs [0021] to [0029] of JP2012-211306A, the contents of which are hereby incorporated by reference.

In addition, with regard to the high-molecular-weight alignment control agent, reference can be made to the description in, for example, paragraphs [0021] to [0057] of JP2004-198511A and paragraphs [0121] to [0167] of JP2006-106662A, the contents of which are hereby incorporated by reference.

Furthermore, examples of the alignment control agent that forms or accelerates the homeotropic alignment include a boronic acid compound and an onium salt compound, and specifically, reference can be made to the compounds described in paragraphs [0023] to [0032] of JP2008-225281A, paragraphs [0052] to [0058] of JP2012-208397A, paragraphs [0024] to [0055] of JP2008-026730A, paragraphs [0043] to [0055] of JP2016-193869A, and the like, the contents of which are hereby incorporated by reference.

On the other hand, the cholesteric alignment can be achieved by adding a chiral agent to the polymerizable liquid crystal composition, and it is possible to control the direction of revolution of the cholesteric alignment by its chiral direction.

Incidentally, it is possible to control the pitch of the cholesteric alignment in accordance with the alignment regulating force of the chiral agent.

In a case where an alignment control agent is contained, a content thereof is preferably 0.01% to 10% by mass, and more preferably 0.05% to 5% by mass with respect to the mass of the total solid content of the composition. In a case where the content is within the range, it is possible to obtain a cured product which has no precipitation or phase separation, alignment defects, or the like, and is uniform and highly transparent while achieving a desired alignment state.

(Other Components)

The polymerizable liquid crystal composition may contain components other than the above-mentioned components, and examples of such other components include a surfactant, a tilt angle control agent, an alignment assistant, a plasticizer, a crosslinking agent, and an amine compound.

Here, the amine compound may have a function of not deteriorating the alignment of the polymerizable liquid crystal compound in a case where the polymerizable liquid crystal composition is stored for several days (for example, about one week) after the preparation. As such an amine compound, an amine compound having a boiling point of 50° C. to 230° C. and having no proton on a nitrogen atom is preferable, secondary amine and tertiary amines are more preferable, and diisopropylethylamine, 4-methylmorpholine, and tributylamine are particularly preferable.

In a case where the amine compound is contained, the content thereof is preferably 0.01% to 10% by mass with respect to the mass of the polymerizable liquid crystal compound.

A method for producing the optically anisotropic layer is not particularly limited, and examples thereof include a method in which a polymerizable liquid crystal composition is applied onto a predetermined substrate (for example, a support which will be described later or an alignment layer provided on the support) to form a coating film, the coating film is subjected to an alignment treatment such that the polymerizable liquid crystal compound is brought into a predetermined alignment state, and then the coating film is subjected to a curing treatment.

The application can be carried out by a known method (for example, a wire bar coating method, an extrusion coating method, a direct gravure coating method, a reverse gravure coating method, and a die coating method).

The alignment treatment can be carried out by drying at room temperature (for example, 20° C. to 25° C.) or by heating. In a case of a thermotropic liquid crystal compound, a liquid crystal phase formed with the alignment treatment can generally be transferred by a change in a temperature or pressure. In a case of a lyotropic liquid crystal compound, the liquid crystal phase can also be transferred according to a compositional ratio of the amount of a solvent.

In a case where the alignment treatment is performed at the heating temperature, the heating time (heating aging time) is preferably 10 seconds to 5 minutes, more preferably 10 seconds to 3 minutes, and still more preferably 10 seconds to 2 minutes.

The curing treatment (irradiation with actinic energy rays (light irradiation treatment) and/or a heating treatment) on the coating film can also be referred to as an immobilization treatment for immobilizing the alignment of the specific liquid crystal compound.

Among those, the light irradiation treatment is preferably carried out. In the polymerization by light irradiation, it is preferable to use ultraviolet rays.

The irradiation dose is preferably 10 mJ/cm² to 50 J/cm², more preferably 20 mJ/cm² to 5 J/cm², still more preferably 30 mJ/cm² to 3 J/cm², and particularly preferably 50 to 1,000 mJ/cm².

In addition, the light irradiation treatment may be carried out under a heating condition in order to accelerate the polymerization reaction.

In the present invention, it is preferable that the optically anisotropic layer formed of the polymerizable liquid crystal composition is an optically anisotropic layer where a liquid crystal state of a smectic phase is immobilized for a reason that the contrast of an image display device thus manufactured is improved.

For the same reason, it is preferable that the optical film of the present invention includes at least one optically anisotropic layer where a liquid crystal state of a smectic phase is immobilized.

In addition, such an optically anisotropic layer is preferably a positive A plate or a positive C plate, and more preferably the positive A plate.

Here, the positive A plate (A plate which is positive) and the positive C plate (C plate which is positive) are defined as follows.

In a case where a refractive index in a film in-plane slow axis direction (in a direction in which an in-plane refractive index is maximum) is defined as nx, a refractive index in an in-plane direction orthogonal to the in-plane slow axis is defined as ny, and a refractive index in a thickness direction is defined as nz, the positive A plate satisfies the relationship of Expression (A1) and the positive C plate satisfies the relationship of Expression (C1). In addition, the positive A plate has an Rth showing a positive value and the positive C plate has an Rth showing a negative value.

nx>ny≈nz Expression (A1)

nz>nx≈ny Expression (C1)

Furthermore, the symbol, “≈”, encompasses not only a case where the both sides are completely the same as each other but also a case where the both are substantially the same as each other.

The expression, “substantially the same”, means that with regard to the positive A plate, for example, a case where (ny−nz)×d (in which d is the thickness of a film) is −10 to 10 nm, and preferably −5 to 5 nm is also included in “ny≈nz”, and a case where (nx−nz)×d is −10 to 10 nm, and preferably −5 to 5 nm is also included in “nx≈nz”. In addition, with regard to the positive C plate, for example, a case where (nx−ny)×d (in which d is the thickness of a film) is 0 to 10 nm, and preferably 0 to 5 nm is also included in “nx≈ny”.

In a case where the optically anisotropic layer is a positive A plate, the Re(550) is preferably 100 to 180 nm, more preferably 120 to 160 nm, still more preferably 130 to 150 nm, and particularly preferably 130 to 140 nm, from the viewpoint that the optically anisotropic layer functions as a λ/4 plate.

Here, the “λ/4 plate” is a plate having a λ/4 function, specifically, a plate having a function of converting a linearly polarized light at a certain specific wavelength into a circularly polarized light (or converting a circularly polarized light to a linearly polarized light).

In the present invention, the thickness of the optically anisotropic layer is not particularly limited, but is preferably 0.1 to 10 m, and more preferably 0.5 to 5 m.

<Support>

The optical film of the embodiment of the present invention may have a support as a base material for forming an optically anisotropic layer as mentioned above.

Such a support is preferably transparent, and specifically, it preferably has a light transmittance of 80% or more.

Examples of such a support include a glass substrate and a polymer film, and examples of the material for the polymer film include cellulose-based polymers; acrylic polymers having an acrylic ester polymer such as polymethyl methacrylate and a lactone ring-containing polymer; thermoplastic norbornene-based polymers; polycarbonate-based polymers; polyester-based polymers such as polyethylene terephthalate and polyethylene naphthalate; styrene-based polymers such as polystyrene and an acrylonitrile-styrene copolymer (AS resin); polyolefin-based polymers such as polyethylene, polypropylene, and an ethylene-propylene copolymer; vinyl chloride-based polymers; amide-based polymers such as nylon and aromatic polyamide; imide-based polymers; sulfone-based polymers; polyether sulfone-based polymers; polyether ether ketone-based polymers; polyphenylene sulfide-based polymers; vinylidene chloride-based polymers; vinyl alcohol-based polymers; vinyl butyral-based polymers; arylate-based polymers; polyoxymethylene-based polymers; epoxy-based polymers; and polymers obtained by mixing these polymers.

In addition, an aspect in which a polarizer which will be described later may also function as such a support is also available.

In the present invention, a thickness of the support is not particularly limited, but is preferably 5 to 60 m, and more preferably 5 to 40 m.

<Alignment Film>

In a case where the optical film of the embodiment of the present invention has any of the above-mentioned supports, it is preferable that the optical film has an alignment film between the support and the cured product. Furthermore, an aspect in which the above-mentioned support may also function as an alignment film is also available.

The alignment film generally has a polymer as a main component. The materials for the polymer material for an alignment film are described in many documents, and many commercially available products can be used.

The polymer material used in the present invention is preferably a polyvinyl alcohol or a polyimide, or a derivative thereof. Particularly, a modified or non-modified polyvinyl alcohol is preferable.

Examples of the alignment film that can be used in the present invention include the alignment films described for Line 24 on Page 43 to Line 8 on Page 49 of WO01/88574A; the modified polyvinyl alcohols described in paragraphs [0071] to [0095] of JP3907735B; and the liquid crystal alignment film formed by a liquid crystal alignment agent described in JP2012-155308A.

In the present invention, for a reason that it is possible to prevent deterioration in the surface condition by avoiding a contact with the surface of an alignment film upon formation of the alignment film, a photo-alignment film is also preferably used as the alignment film.

The photo-alignment film is not particularly limited, but the polymer materials such as a polyamide compound and a polyimide compound, described in paragraphs [0024] to [0043] of WO2005/096041A; the liquid crystal alignment film formed by a liquid crystal alignment agent having a photo-alignment group, described in JP2012-155308A; LPP-JP265CP, trade name, manufactured by Rolic Technologies Ltd.; or the like can be used.

In addition, in the present invention, the thickness of the alignment film is not particularly limited, but from the viewpoint of forming an optically anisotropic layer having a uniform film thickness by mitigating the surface roughness that can be present on the support, the thickness is preferably 0.01 to 10 m, more preferably 0.01 to 1 m, and still more preferably 0.01 to 0.5 m.

<Ultraviolet Absorber>

The optical film of the embodiment of the present invention preferably includes an ultraviolet (UV) absorber, taking an effect of external light (particularly ultraviolet rays) into consideration.

The ultraviolet absorber may be contained in the optically anisotropic layer or may be contained in a member other than the optically anisotropic layer. Suitable examples of the member other than the optically anisotropic layer include a support.

As the ultraviolet absorber, any one of ultraviolet absorbers known in the related art, which can express ultraviolet absorptivity, can be used. Among such the ultraviolet absorbers, a benzotriazole-based or hydroxyphenyltriazine-based ultraviolet absorber is preferably used from the viewpoint that it has high ultraviolet absorptivity and ultraviolet absorbing ability (ultraviolet-shielding ability) used for an image display device is obtained.

In addition, in order to broaden ultraviolet absorbing ranges, two or more kinds of ultraviolet absorbers having different maximum absorption wavelengths can be used in combination.

Specific examples of the ultraviolet absorber include the compounds described in paragraphs [0258] and [0259] of JP2012-18395A and the compounds described in paragraphs [0055] to [0105] of JP2007-72163A.

In addition, as a commercially available product thereof, for example, Tinuvin 400, Tinuvin 405, Tinuvin 460, Tinuvin 477, Tinuvin 479, and Tinuvin 1577 (all manufactured by BASF), or the like can be used.

[Adhesive Layer]

In the polarizing plate of the embodiment of the present invention, an adhesive layer is disposed between the above-mentioned polarizer and optical film.

The adhesive layer included in the polarizing plate of the embodiment of the present invention is a layer formed of an adhesive composition containing a polymerizable compound and a polymerization initiator, as described above.

In addition, in the polarizing plate of the embodiment of the present invention, the polymerization initiator included in the adhesive composition satisfies the following conditions 1 and 2. Furthermore, in a case where the adhesive composition includes a plurality of types of polymerization initiators, it is sufficient that any one of the polymerization initiators satisfies the conditions 1 and 2 shown below.

Condition 1: A maximum absorption wavelength of the polymerization initiator is within ±70 nm of a minimum absorption wavelength of the optical film

Condition 2: A molar absorption coefficient of the polymerization initiator is 22,000 mol⁻¹Lcm⁻¹ or more

Here, in a method for measuring a maximum absorption wavelength of the polymerization initiator, an absorption spectrum (measurement range: 200 to 800 nm) is measured with a spectrophotometer (UV-3150, manufactured by Shimadzu Corporation), using a solution prepared by dissolving 5 mg of the polymerization initiator in 1,000 mL of chloroform), to determine the maximum absorption wavelength.

In addition, in a method for measuring a minimum absorption wavelength of the optical film, an absorption spectrum (measurement range: 200 to 800 nm) is measured with a spectrophotometer (UV-3150, manufactured by Shimadzu Corporation), using a 40 mm square optical film, to determine the minimum absorption wavelength.

Moreover, in a method for measuring a molar absorption coefficient of the polymerization initiator, an absorbance of the solution is measured with a spectrophotometer (UV-3150, manufactured by Shimadzu Corporation), using a solution prepared by dissolving 5 mg of the polymerization initiator in 1,000 mL of chloroform, to calculate the molar absorption coefficient F from the following expression. Incidentally, the optical path length of a cell used in this measurement is 1 cm.

A=ε·C·l Expression:

(A: an absorbance, C: a concentration (mol/L), and 1: an optical path length (cm))

It is preferable that both the maximum absorption wavelength of the polymerization initiator and the minimum absorption wavelength of the optical film are each in a range of 250 to 400 nm.

The adhesive composition is not particularly limited as long as it is a composition containing a polymerizable compound and a polymerization initiator, and is an actinic energy ray-curable adhesive composition such as an electron beam-curable adhesive composition, an ultraviolet ray-curable adhesive composition, and a visible light-curable adhesive composition, and more preferably the ultraviolet ray-curable adhesive composition.

<Polymerizable Compound>

Examples of the polymerizable compound included in the adhesive composition include a cationically polymerizable compound and a radically polymerizable compound, known in the related art.

(Cationically Polymerizable Compound)

Examples of the cationically polymerizable compound include a monofunctional cationically polymerizable compound having one cationically polymerizable functional group in the molecule and a polyfunctional cationically polymerizable compound having two or more cationically polymerizable functional groups in the molecule.

Examples of the cationically polymerizable functional group include an epoxy group, an oxetanyl group, and a vinyl ether group.

Examples of the compound having an epoxy group include phenyl glycidyl ether, p-tert-butylphenyl glycidyl ether, butyl glycidyl ether, 2-ethylhexyl glycidyl ether, allyl glycidyl ether, 1,2-butylene oxide, 1,3-butadiene monooxide, 1,2-epoxydodecane, epichlorohydrin, 1,2-epoxydecane, styrene oxide, cyclohexene oxide, 3-methacryloyloxymethylcyclohexene oxide, 3-acryloyloxymethylcyclohexene oxide, 3-vinylcyclohexene oxide, and 4-vinylcyclohexene oxide.

Examples of the compound having an oxetanyl group include 3-ethyl-3-hydroxymethyloxetane, 1,4-bis[(3-ethyl-3-oxetanyl)methoxymethyl]benzene, and 3-ethyl-3-(phenoxymethyl)oxetane, di[(3-ethyl-3-oxetanyl)methyl] ether, 3-ethyl-3-(2-ethylhexyloxymethyl)oxetane, and phenol novolac oxetane.

Examples of the compound having a vinyl ether group include vinyl ethers such as 2-hydroxyethyl vinyl ether, diethylene glycol monovinyl ether, 4-hydroxybutyl vinyl ether, and diethylene glycol, triethylene glycol divinyl ether, cyclohexanedimethanol divinyl ether, cyclohexanedimethanol monovinyl ether, tricyclodecane vinyl ether, cyclohexyl vinyl ether, methoxyethyl vinyl ether, ethoxyethyl vinyl ether, and pentaerythritol type tetravinyl ether.

(Radically Polymerizable Compound)

Examples of the radically polymerizable compound include a compound having a radically polymerizable functional group with a carbon-carbon double bond, such as a (meth)acryloyl group and a vinyl group.

In addition, as the radically polymerizable compound, either a monofunctional radically polymerizable compound or a bifunctional or higher functional radically polymerizable compound can be used.

Examples of the monofunctional radically polymerizable compound include a (meth)acrylamide derivative having a (meth)acrylamide group and various (meth)acrylic acid derivatives having a (meth)acryloyloxy group.

Specific examples of the (meth)acrylamide derivative include N-alkyl group-containing (meth)acrylamide derivatives such as N-methyl (meth)acrylamide, N,N-dimethyl (meth)acrylamide, N,N-diethyl (meth)acrylamide, N-isopropyl (meth)acrylamide, N-butyl (meth)acrylamide, and N-hexyl (meth)acrylamide; N-hydroxyalkyl group-containing (meth)acrylamide derivatives such as N-methylol (meth)acrylamide, N-hydroxyethyl (meth)acrylamide, and N-methylol-N-propane (meth)acrylamide; N-aminoalkyl group-containing (meth)acrylamide derivatives such as aminomethyl (meth)acrylamide and aminoethyl (meth)acrylamide; N-alkoxy group-containing (meth)acrylamide derivatives such as N-methoxymethylacrylamide and N-ethoxymethylacrylamide; and N-mercaptoalkyl group-containing (meth)acrylamide derivatives such as mercaptomethyl (meth)acrylamide and mercaptoethyl (meth)acrylamide.

Specific examples of the (meth)acrylic acid derivative include:
alkyl (meth)acrylate esters (having 1 to 20 carbon atoms) such as methyl (meth)acrylate, ethyl (meth)acrylate, n-propyl (meth)acrylate, isopropyl (meth)acrylate, 2-methyl-2-nitropropyl (meth)acrylate, n-butyl (meth)acrylate, isobutyl (meth)acrylate, s-butyl (meth)acrylate, t-butyl (meth)acrylate, n-pentyl (meth)acrylate, t-pentyl (meth)acrylate, 3-pentyl (meth)acrylate, 2,2-dimethylbutyl (meth)acrylate, n-hexyl (meth)acrylate, cetyl (meth)acrylate, n-octyl (meth)acrylate, 2-ethylhexyl (meth)acrylate, 4-methyl-2-propylpentyl (meth)acrylate, and n-octadecyl (meth)acrylic acid;
cycloalkyl (meth)acrylates such as cyclohexyl (meth)acrylate and cyclopentyl (meth)acrylate;
aralkyl (meth)acrylates such as benzyl (meth)acrylate;
polycyclic (meth)acrylates such as 2-isobornyl (meth)acrylate, 2-norbornylmethyl (meth)acrylate, 5-norbornen-2-yl-methyl (meth)acrylate, 3-methyl-2-norbornylmethyl (meth)acrylate, dicyclopentenyl (meth)acrylate, dicyclopentenyloxyethyl (meth)acrylate, and dicyclopentanyl (meth)acrylate;
alkoxy group- or phenoxy group-containing (meth)acrylates such as 2-methoxyethyl (meth)acrylate, 2-ethoxyethyl (meth)acrylate, 2-methoxymethoxyethyl (meth)acrylate, 3-methoxybutyl (meth)acrylate, ethyl carbitol (meth)acrylate, phenoxyethyl (meth)acrylate, and alkylphenoxypolyethylene glycol (meth)acrylate;
hydroxyl group-containing (meth)acrylates such as 2-hydroxyethyl (meth)acrylate, 2-hydroxypropyl (meth)acrylate, 3-hydroxypropyl (meth)acrylate, 2-hydroxybutyl (meth)acrylate, 4-hydroxybutyl (meth)acrylate, 6-hydroxyhexyl (meth)acrylate, 8-hydroxyoctyl (meth)acrylate, 10-hydroxydecyl (meth)acrylate, and 12-hydroxylauryl (meth)acrylate, or hydroxyl group-containing (meth)acrylates such as [4-(hydroxymethyl)cyclohexyl]methyl acrylate, cyclohexanedimethanol mono(meth)acrylate, and 2-hydroxy-3-phenoxypropyl (meth)acrylate;
epoxy group-containing (meth)acrylates such as glycidyl (meth)acrylate and 4-hydroxybutyl (meth)acrylate glycidyl ether;
halogen-containing (meth)acrylates such as 2,2,2-trifluoroethyl (meth)acrylate, 2,2,2-trifluoroethyl ethyl (meth)acrylate, tetrafluoropropyl (meth)acrylate, hexafluoropropyl (meth)acrylate, octafluoropentyl (meth)acrylate, heptadecafluorodecyl (meth)acrylate, and 3-chloro-2-hydroxypropyl (meth)acrylate;
alkylaminoalkyl (meth)acrylates such as dimethylaminoethyl (meth)acrylate;
oxetane group-containing (meth)acrylates such as 3-oxetanylmethyl (meth)acrylate, 3-methyl-oxetanylmethyl (meth)acrylate, 3-ethyl-oxetanylmethyl (meth)acrylate, 3-butyl-oxetanylmethyl (meth)acrylate, and 3-hexyl-oxetanylmethyl (meth)acrylate; and
heterocycle-containing (meth)acrylates such as tetrahydrofurfuryl (meth)acrylate and butyrolactone (meth)acrylate.

Examples of the monofunctional radically polymerizable compound include carboxyl group-containing monomers such as (meth)acrylic acid, carboxyethyl acrylate, carboxypentyl acrylate, itaconic acid, maleic acid, fumaric acid, crotonic acid, and isocrotonic acid.

In addition, examples of the monofunctional radically polymerizable compound include lactam-based vinyl monomers such as N-vinylpyrrolidone, N-vinyl-F-caprolactam, and methyl vinylpyrrolidone; and vinyl-based monomers having a nitrogen-containing heterocycle, such as vinylpyrrole, vinylimidazole, vinyloxazole, and vinylmorpholine.

Moreover, as the monofunctional radically polymerizable compound, a radically polymerizable compound having an active methylene group can be used. The radically polymerizable compound having an active methylene group is a compound that has an active double-bonding group such as a (meth)acrylic group at a terminal or in the molecule and has an active methylene group. Examples of the active methylene group include an acetoacetyl group, an alkoxymalonyl group, and a cyanoacetyl group, and the acetoacetyl group is preferable.

Specific examples of the radically polymerizable compound having an active methylene group include c(meth)acrylate; 2-ethoxymalonyloxyethyl (meth)acrylate, 2-cyanoacetoxyethyl (meth)acrylate, N-(2-cyanoacetoxyethyl) acrylamide, N-(2-propionyl)acetoxybutyl) acrylamide, N-(4-acetoacetoxymethylbenzyl) acrylamide, and N-(2-acetoacetylaminoethyl) acrylamide.

The radically polymerizable compound having an active methylene group is preferably acetoacetoxyalkyl (meth)acrylate.

Examples of the bifunctional or higher polyfunctional radically polymerizable compound include esterified products of a (meth)acrylate and a polyhydric alcohol, such as N,N′-methylene bis(meth)acrylamide, tripropylene glycol di(meth)acrylate, tetraethylene glycol di(meth)acrylate, 1,6-hexanediol di(meth)acrylate, 1,9-nonanediol di(meth)acrylate, 1,10-decanediol diacrylate, 2-ethyl-2-butylpropanediol di(meth)acrylate, bisphenol A di(meth)acrylate, a bisphenol A-ethylene oxide adduct di(meth)acrylate, a bisphenol A-propylene oxide adduct di(meth)acrylate, a bisphenol A-diglycidyl ether di(meth)acrylate, neopentyl glycol di(meth)acrylate, tricyclodecanedimethanol di(meth)acrylate, cyclic trimethylolpropane formal (meth)acrylate, dioxane glycol di(meth)acrylate, trimethylolpropane tri(meth)acrylate, pentaerythritol tri(meth)acrylate, pentaerythritol tetra(meth)acrylate, dipentaerythritol penta(meth)acrylate, dipentaerythritol hexa(meth)acrylate, and EO-modified diglycerin tetra(meth)acrylate, which are polyfunctional (meth)acrylamide derivatives, and 9,9-bis[4-(2-(meth)acryloyloxyethoxy)phenyl]fluorene.

<Polymerization Initiator>

As the polymerization initiator included in the adhesive composition, a photocationic polymerization initiator or photoradical polymerization initiator known in the related art, which satisfies the above-mentioned conditions 1 and 2, can be appropriately used.

(Photocationic Polymerization Initiator)

The photocationic polymerization initiator generates a cationic species or a Lewis acid by irradiation with actinic energy rays such as visible light, ultraviolet rays, X-rays, and electron beams, and initiates a polymerization reaction of an epoxy group or an oxetanyl group.

As the photocationic polymerization initiator, for example, a known sulfonium salt, ammonium salt, iodonium salt (for example, a diaryliodonium salt), triarylsulfonium salt, diazonium salt, or iminium salt can be used as the component (e). More specific examples of the photocationic polymerization initiator include the photocationic polymerization initiator represented by each of Formulae (25) to (28) shown in paragraphs 0050 to 0053 of JP1996-143806A (JP-08-143806A), and those exemplified as a cationic polymerization catalyst in paragraph 0020 of JP1996-283320A (JP-H08-283320A).

(Photoradical Polymerization Initiator)

Examples of the photoradical polymerization initiator include benzophenone-based compounds such as benzyl, benzophenone, benzoylbenzoic acid, and 3,3′-dimethyl-4-methoxybenzophenone; aromatic ketone compounds such as 4-(2-hydroxyethoxy)phenyl (2-hydroxy-2-propyl) ketone, α-hydroxy-α,α′-dimethylacetophenone, 2-methyl-2-hydroxypropiophenone, and α-hydroxycyclohexyl phenyl ketone; acetophenone-based compounds such as methoxyacetophenone, 2,2-dimethoxy-2-phenylacetophenone, 2,2-diethoxyacetophenone, and 2-methyl-1-[4-(methylthio)-phenyl]-2-morpholinopropane-1; benzoin ether-based compounds such as benzoin methyl ether, benzoin ethyl ether, benzoin isopropyl ether, benzoin isobutyl ether, and anisoin methyl ether; aromatic ketal-based compounds such as benzyl dimethyl ketal; aromatic sulfonyl chloride-based compounds such as 2-naphthalenesulfonyl chloride; optically active oxime-based compounds such as 1-phenone-1,1-propanedione-2-(o-ethoxycarbonyl)oxime; thioxanthone-based compounds such as thioxanthone, 2-chlorothioxanthone, 2-methylthioxanthone, 2,4-dimethylthioxanthone, isopropylthioxanthone, 2,4-dichlorothioxanthone, 2,4-diethylthioxanthone, 2,4-diisopropylthioxanthone, and dodecylthioxanthone; camphor quinone; halogenated ketones; acylphosphinoxide; and acyl phosphonate.

<Sensitizer>

For a reason that the durability of the polarizing plate is further improved, it is preferable that the adhesive composition contains a sensitizer, and it is more preferable that the adhesive composition contains a sensitizer having a maximum absorption wavelength that is on a longer wavelength side than the maximum absorption wavelength of the polymerization initiator and in a wavelength range where the transmittance of the optical film is 1% or more. Here, in a method for measuring a maximum absorption wavelength of the sensitizer, an absorption spectrum (measurement range: 200 to 800 nm) is measured with a spectrophotometer (UV-3150, manufactured by Shimadzu Corporation), using a solution prepared by dissolving 5 mg of the polymerization initiator in 1,000 mL of chloroform), to determine the maximum absorption wavelength.

In addition, in a method for measuring a transmittance of the optical film, a transmittance (measurement range: 200 to 800 nm) is measured with a spectrophotometer (UV-3150, manufactured by Shimadzu Corporation), using a 40 mm square optical film, to determine the transmittance.

The maximum absorption wavelength of the sensitizer is preferably in a range of 250 to 400 nm.

Such a sensitizer is preferably a photosensitizer, and specific examples thereof include xanthone compounds such as xanthone and thioxanthone (for example, 2,4-diethylthioxanthone and 2-isopropylthioxanthone); anthracene compounds of anthracene and an alkoxy group-containing anthracene (for example, dibutoxyanthracene); phenothiazine, and rubrene.

In a case where the adhesive composition contains a sensitizer, the content of the sensitizer is preferably 0.1 to 30 parts by mass, more preferably 0.5 to 10 parts by mass, and still more preferably 0.5 to 8 parts by mass with respect to 100 parts by mass of the polymerizable compound.

[Polymer]

In the polarizing plate of the embodiment of the present invention, for a reason that the adhesiveness between the polarizer and the optical film is further improved, it is preferable that a polymer having a repeating unit represented by Formula (B) is present on a surface of the optical film on the adhesive layer side (hereinafter simply referred to as a “surface A1” in the present paragraph) or on a surface of the adhesive layer on the optical film side (hereinafter simply referred to as a “surface A2” in the present paragraph), and for a reason that the adhesiveness between the polarizer and the optical film is further improved, it is more preferable that the polymer having a repeating unit represented by Formula (B) is present on the surface A1.

Here, the presence or absence of the polymer on the surface A1 and the surface A2 can be confirmed by, for example, a time-of-flight secondary ion mass spectrometry method (TOF-SIMS). Furthermore, for TOF-SIMS, the method described in “Surface Analysis Technology Library Secondary Ion Mass Spectrometry” edited by the Surface Science Society of Japan and published by Maruzen Co., Ltd. (published in 1999) can be adopted.

Specifically, in a case where the polymer is present on the surface A1 or the surface A2, a fragment derived from the repeating unit represented by Formula (B) is detected together.

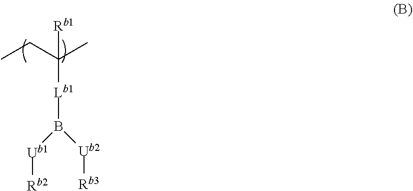

In Formula (B), R^{b1} represents a hydrogen atom, a fluorine atom, a chlorine atom, or an alkyl group having 1 to 20 carbon atoms.

In addition, L^{b1} represents a single bond or a divalent linking group.

Moreover, U^{b1} and U^{b2} each independently represent —O—, —S—, —COO—, —OCO—, —CONH—, —NHCOO—, or —NH—.

In addition, R^{b2} and R^{b3} each independently represent a hydrogen atom, a substituted or unsubstituted aliphatic hydrocarbon group, a substituted or unsubstituted aryl group, or a substituted or unsubstituted heteroaryl group. It should be noted that R^{b2} and R^{b3} may be bonded to each other through a linking group.

In Formula (B), as the alkyl group having 1 to 20 carbon atoms, represented by one aspect of R^{b1}, an alkyl group having 1 to 10 carbon atoms is preferable, an alkyl group having 1 to 8 carbon atoms (for example, a methyl group, an ethyl group, a propyl group, an isopropyl group, an n-butyl group, an isobutyl group, a sec-butyl group, a t-butyl group, and a cyclohexyl group) is more preferable, an alkyl group having 1 to 4 carbon atoms is still more preferable, and the methyl group or the ethyl group is particularly preferable.

R^{b1} preferably represents a hydrogen atom or a methyl group.

Examples of the divalent linking group represented by one aspect of L^{b1} include a divalent linking group selected from the group consisting of —O—, —S—, —COO—, —OCO—, —CONR^{b4}—, —NR^{b4}COO—, —CR^{b4}N—, a substituted or unsubstituted divalent aliphatic group, a substituted or unsubstituted divalent aromatic group, and a combination thereof, and R⁴ represents a hydrogen atom or an alkyl group having 1 to 20 carbon atoms. In addition, specific examples of the substituent which may be contained in the divalent aliphatic group or the like include the same ones as the specific examples described in the substituent group Y which will be described later, and specific examples of R⁴ include the same ones as the specific examples of R^{b}.

Among these divalent linking groups, a divalent linking group selected from the group consisting of —O—, —COO—, —OCO—, —CONR⁹—, —NR⁹COO—, the substituted or unsubstituted divalent aliphatic group, the substituted or unsubstituted divalent aromatic group, and a combination thereof are preferable.

In a case where L^{b1} includes the substituted or unsubstituted divalent aromatic group, the number of the aromatic rings is preferably 1 to 3, more preferably 1 or 2, and still more preferably 1.

In Formula (B), U^{b1} and U^{b}2 each independently represent —O—, —S—, —COO—, —OCO—, —CONH—, —NHCOO—, or —NH, as mentioned above, and is preferably —O— or —NH—, and more preferably —O—.

In Formula (B), examples of the substituted or unsubstituted aliphatic hydrocarbon group represented by one aspect of R^{b2} and R^{b3} include an alkyl group, an alkenyl group, or an alkynyl group, each of which may have a substituent.

Specific examples of the alkyl group include linear, branched, or cyclic alkyl groups such as a methyl group, an ethyl group, a propyl group, a butyl group, a pentyl group, a hexyl group, a heptyl group, an octyl group, a nonyl group, a decyl group, an undecyl group, a dodecyl group a tridecyl group, a hexadecyl group, an octadecyl group, an eicosyl group, an isopropyl group, an isobutyl group, a sec-butyl group, a tert-butyl group, an isopentyl group, a neopentyl group, a 1-methylbutyl group, an isohexyl group, a 2-methylhexyl group, a cyclopentyl group, a cyclohexyl group, a 1-adamantyl group, and a 2-norbornyl group.

Specific examples of the alkenyl group include linear, branched, or cyclic alkenyl groups such as a vinyl group, a 1-propenyl group, a 1-butenyl group, a 1-methyl-1-propenyl group, a 1-cyclopentenyl group, and a 1-cyclohexenyl group.

Specific examples of the alkynyl group include an ethynyl group, a 1-propynyl group, a 1-butynyl group, and a 1-octynyl group.

In addition, examples of the substituted or unsubstituted aryl group represented by one aspect of R^{b2} and R^{b3} include those in which 1 to 4 benzene rings form a fused ring and those in which a benzene ring and an unsaturated five-membered ring form a fused ring, and specific examples thereof include a phenyl group, a naphthyl group, an anthryl group, a phenanthryl group, an indenyl group, an acenaphthenyl group, a fluorenyl group, and a pyrenyl group.

Moreover, examples of the substituted or unsubstituted heteroaryl group represented by one aspect of R^{b2} and R^{b3} include a heteroaryl group obtained by removing one hydrogen atom on a heteroaromatic ring including one or more heteroatoms selected from the group consisting of a nitrogen atom, an oxygen atom, and a sulfur atom.

Specific examples of the heteroaromatic ring including one or more heteroatoms selected from the group consisting of a nitrogen atom, an oxygen atom, and a sulfur atom include pyrrole, furan, thiophene, pyrazole, imidazole, triazole, oxazole, isoxazole, oxadiazole, thiazole, thiadiazole, indole, carbazole, benzofuran, dibenzofuran, thianaphthene, dibenzothiophene, indazole benzimidazole, anthranil, benzisoxazole, benzoxazole, benzothiazole, purine, pyridine, pyridazine, pyrimidine, pyrazine, triazine, quinoline, acridine, isoquinoline, phthalazine, quinazoline, quinoxaline, naphthyridine, phenanthroline, and pteridine.

Examples of the substituents which may be contained in R^{b2} and R^{b3} include monovalent non-metal atomic groups from which hydrogen is removed, and are selected from the following substituent group Y, for example.

(Substituent Group Y)

A halogen atom (—F, —Br, —Cl, and —I), a hydroxyl group, an alkoxy group, an aryloxy group, a mercapto group, an alkylthio group, an arylthio group, an alkyldithio group, an aryldithio group, an amino group, an N-alkylamino group, an N,N-dialkylamino group, an N-arylamino group, an N,N-diarylamino group, an N-alkyl-N-arylamino group, an acyloxy group, a carbamoyloxy group, an N-alkylcarbamoyloxy group, an N-arylcarbamoyloxy group, an N,N-dialkylcarbamoyloxy group, an N,N-diarylcarbamoyloxy group, an N-alkyl-N-arylcarbamoyloxy group, an alkylsulfoxy group, an arylsulfoxy group, an acylthio group, an acylamino group, an N-alkylacylamino group, an N-arylacylamino group, a ureide group, an N′-alkylureide group, an N′,N′-dialkylureide group, an N′-arylureide group, an N′,N′-diarylureide group, an N′-alkyl-N′-arylureide group, an N-alkylureide group, an N-arylureide group, an N′-alkyl-N-alkylureide group, an N′-alkyl-N-arylureide group, an N′,N′-dialkyl-N-alkylureide group, an N′,N′-dialkyl-N-arylureide group, an N′-aryl-N-alkylureide group, an N′-aryl-N-arylureide group, an N′,N′-diaryl-N-alkylureide group, an N′,N′-diaryl-N-arylureide group, an N′-alkyl-N′-aryl-N-alkylureide group, an N′-alkyl-N′-aryl-N-arylureide group, an alkoxycarbonylamino group, an aryloxycarbonylamino group, an N-alkyl-N-alkoxycarbonylamino group, an N-alkyl-N-aryloxycarbonylamino group, an N-aryl-N-alkoxycarbonylamino group, an N-aryl-N-aryloxycarbonylamino group, a formyl group, an acyl group, a carboxyl group and a conjugate base group thereof, an alkoxycarbonyl group, an aryloxycarbonyl group, a carbamoyl group, an N-alkylcarbamoyl group, an N,N-dialkylcarbamoyl group, an N-arylcarbamoyl group, an N,N-diarylcarbamoyl group, an N-alkyl-N-arylcarbamoyl group, an alkylsulfinyl group, an arylsulfinyl group, an alkylsulfonyl group, an arylsulfonyl group, a sulfo group (—SO₃H) and a conjugate base group thereof, an alkoxysulfonyl group, an aryloxysulfonyl group, sulfinamoyl group, an N-alkylsulfinamoyl group, an N,N-dialkylsulfinamoyl group, an N-arylsulfinamoyl group, an N,N-diarylsulfinamoyl group, an N-alkyl-N-arylsulfinamoyl group, a sulfamoyl group, an N-alkylsulfamoyl group, an N,N-dialkylsulfamoyl group, an N-arylsulfamoyl group, an N,N-diarylsulfamoyl group, an N-alkyl-N-arylsulfamoyl group, an N-acylsulfamoyl group and a conjugate base group thereof, an N-alkylsulfonylsulfamoyl group (—SO₂NHSO₂(alkyl)) and a conjugate base group thereof, an N-arylsulfonylsulfamoyl group (—SO₂NHSO₂(aryl)) and a conjugate base group thereof, an N-alkylsulfonylcarbamoyl group (—CONHSO₂(alkyl)) and a conjugate base group thereof, an N-arylsulfonylcarbamoyl group (—CONHSO₂(aryl)) and a conjugate base group thereof, an alkoxysilyl group (—Si(Oalkyl)₃), an aryloxysilyl group (—Si(Oaryl)₃), a hydroxysilyl group (—Si(OH)₃) and a conjugate base group thereof, a phosphono group (—PO₃H2) and a conjugate base group thereof, a dialkylphosphono group (—PO₃(alkyl)₂), a diarylphosphono group (—PO₃(aryl)₂), an alkylarylphosphono group (—PO₃(alkyl)(aryl)), a monoalkylphosphono group (—PO₃H(alkyl)) and a conjugate base group thereof, a monoarylphosphono group (—PO₃H(aryl)) and a conjugate base group thereof, a phosphonooxy group (—OPO₃H₂) and a conjugate base group thereof, a dialkylphosphonooxy group (—OPO₃(alkyl)₂), a diarylphosphonooxy group (—OPO₃(aryl)₂), an alkylarylphosphonooxy group (—OPO₃(alkyl)(aryl)), a monoalkylphosphonooxy group (—OPO₃H(alkyl)) and a conjugated base group thereof, a monoarylphosphonooxy group (—OPO₃H(aryl)) and a conjugated base group thereof, a cyano group, a nitro group, an aryl group, an alkenyl group and an alkynyl group, in which these substituents may be bonded to each other or bonded to a hydrocarbon group which is substituted to form a ring, as possible.

R^{b2} and R^{b3} in Formula (B) are each preferably the hydrogen atom, the substituted or unsubstituted alkyl group, or the substituted or unsubstituted aryl group, more preferably the hydrogen atom or the substituted or unsubstituted alkyl group, and still more preferably the hydrogen atom or both linked to each other through an alkylene linking group.

Specific examples of the monomer forming the repeating unit represented by Formula (B) include monomers represented by Formulae 3-1 to 3-26.

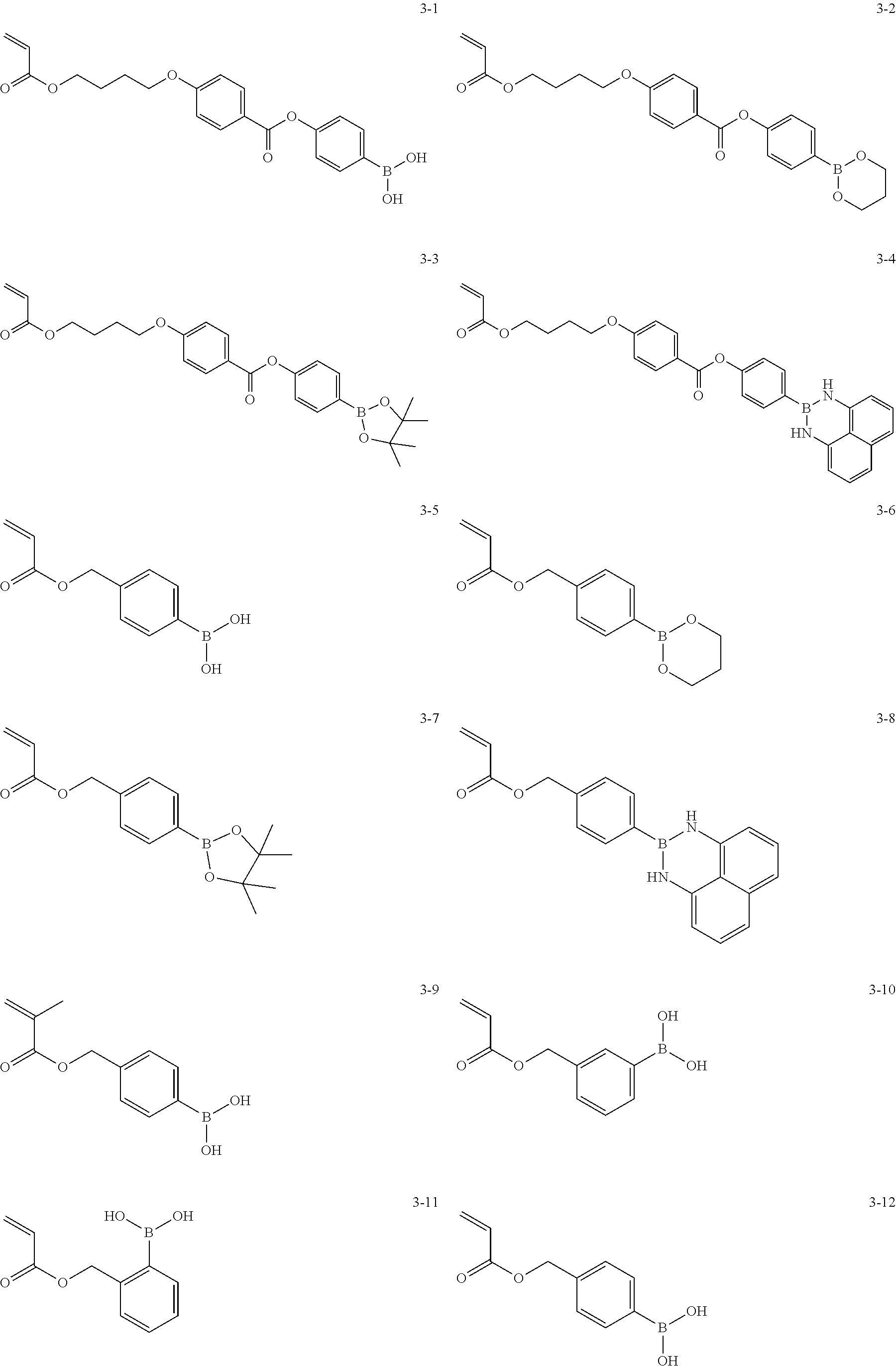

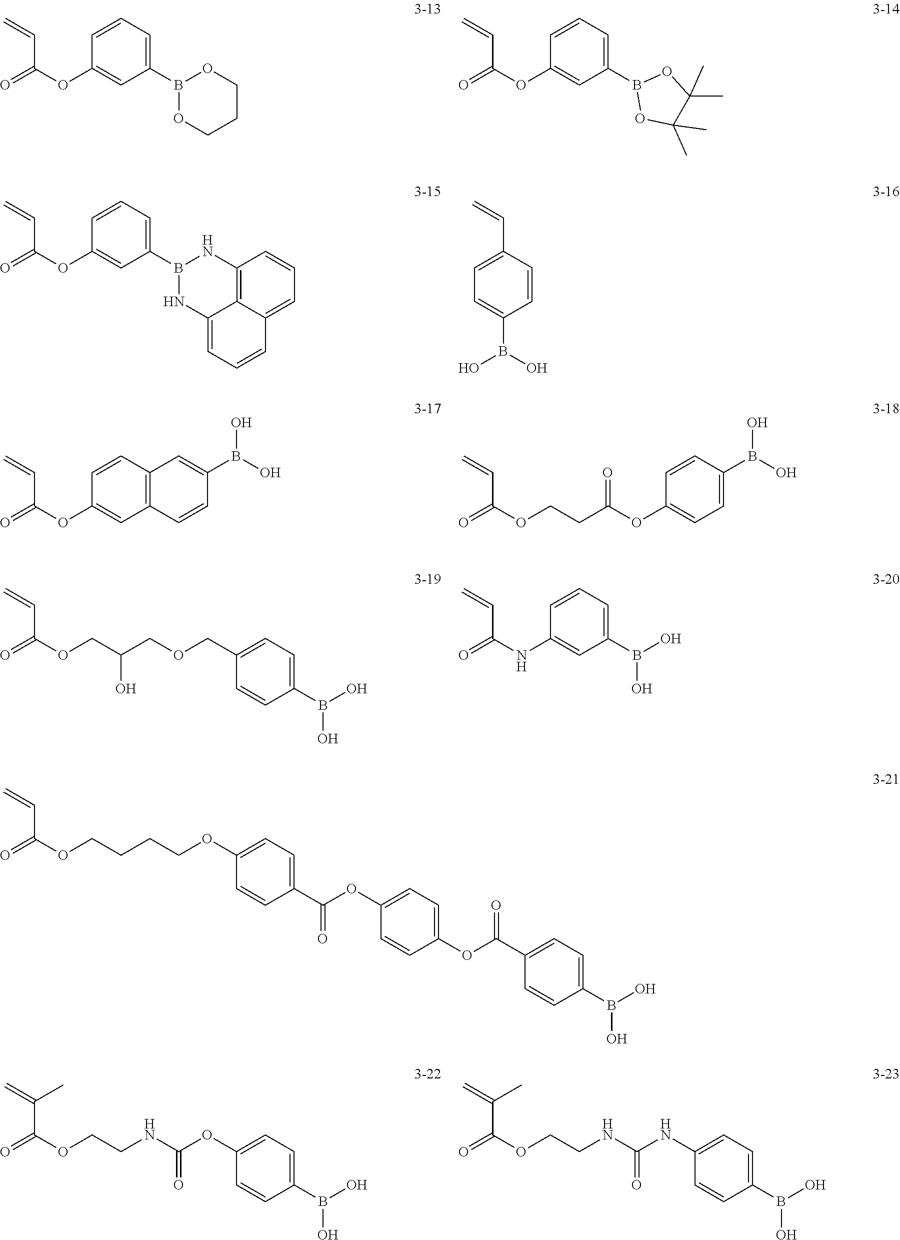

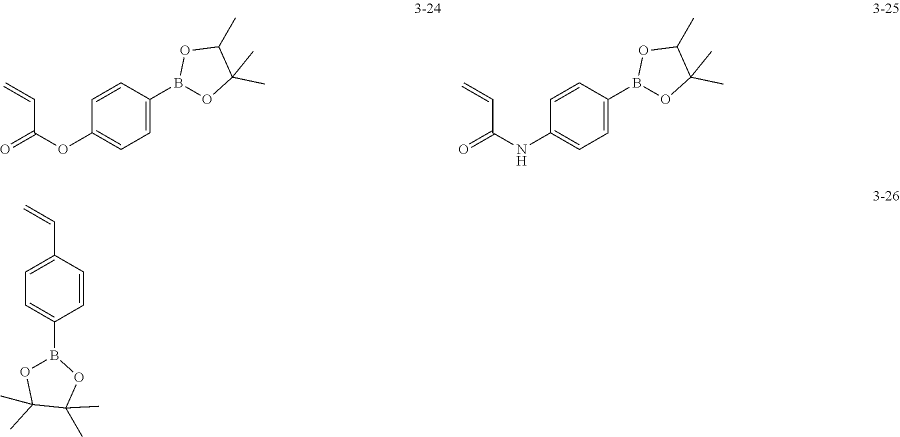

In the present invention, it is preferable that the polymer is a copolymer further having a repeating unit represented by Formula (F) for a reason that the adhesiveness between the polarizer and the optical film is further improved.

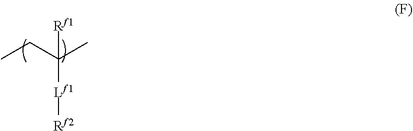

In Formula (F), R^{f1} represents a hydrogen atom, a fluorine atom, a chlorine atom, or an alkyl group having 1 to 20 carbon atoms.

In addition, L^{f1} represents a single bond or a divalent linking group.

Moreover, R^{f2} represents a group including at least one group of (a), (b), or (c) below.
(a) A group represented by any of Formulae (1) to (3)
(b) A perfluoropolyether group
(c) An alkyl group having a hydrogen bond between a proton donor functional group and a proton acceptor functional group, and having at least one carbon atom having a fluorine atom as a substituent and having 1 to 20 carbon atoms

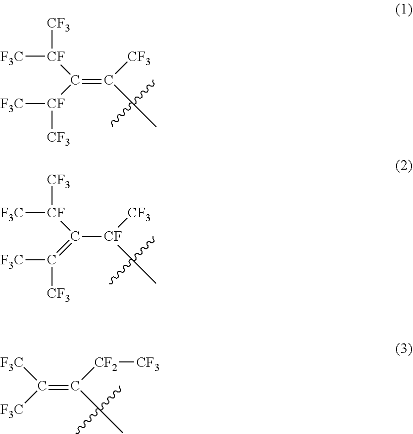

In Formula (F), examples of the alkyl group having 1 to 20 carbon atoms, represented by one aspect of R^{f}, include the same ones as those of the alkyl group having 1 to 20 carbon atoms, represented by one aspect of R^{b1} in Formula (B). Among those, an alkyl group having 1 to 4 carbon atoms is preferable, and a methyl group or an ethyl group is particularly preferable. R^{f1} preferably represents a hydrogen atom or a methyl group.

Examples of the divalent linking group represented by one aspect of L^{f1} in Formula (F) include the same ones as those of the divalent linking group represented by one aspect of L^{b1} in Formula (B). Among those, —O—, —CO—O—, —CO—NH—, and —O—CO— are preferable.

In Formula (F), R^{f} represents a group including at least one group of (a), (b), or (c).

(a) Repeating Unit Having Group Represented by Formula (1), (2), or (3)

In a case where RF1 of Formula (F-1) includes a group represented by Formula (1), (2), or (3), it is also preferable that Formula (F-1) is a repeating unit represented by Formula (4).

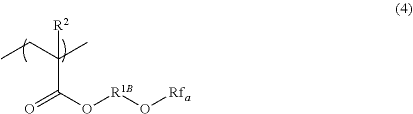

In Formula (4), a is the group represented by Formula (1), (2), or (3).

In Formula (4), R^{1B} is a divalent group having 2 to 50 carbon atoms. The divalent group having 2 to 50 carbon atoms, represented by R^{1B}, may include a heteroatom, and may be an aromatic group, a heteroaromatic group, a heterocyclic group, an aliphatic group, or an alicyclic group.

Specific examples of R^{1B} include the following groups.
—(CH₂)ₙ₁— (n1=2 to 50)
   —X—Y—(CH₂)ₙ₂— (n2=2 to 43)
   —X—(CH₂)ₙ₃— (n3=1 to 44)
   —CH₂CH₂(OCH₂CH₂)ₙ₄— (n4=1 to 24)
   —XCO(OCH₂CH₂)ₙ₅— (n5=1 to 21)

In the formulae, X represents phenylene, biphenylene, or naphthylene, which may have 1 to 3 substituents selected from the group consisting of an alkyl group having 1 to 3 carbon atoms (a methyl group, an ethyl group, and a propyl group), an alkoxy group having 1 to 4 carbon atoms (a methoxy group, an ethoxy group, a propoxy group, a butoxy group, and the like), and a halogen atom (F, Cl, Br, and I). Y represents —O—CO—, —CO—O—, —CONH—, or —NHCO—.

X is preferably 1,2-phenylene, 1,3-phenylene, or 1,4-phenylene, and more preferably 1,4-phenylene.

Particularly preferred examples of the divalent group having 2 to 50 carbon atoms, represented by R^{1B}, include divalent groups having the following structures.
—(CH₂)ₙ₁— (n1=2 to 10)
   —C₆H₄OCO(CH₂)ₙ₂— (n2=2 to 10)
   —C₆H₄(CH₂)ₙ₃— (n3=1 to 10)
   —CH₂CH₂(OCH₂CH₂)ₙ₄— (n4=1 to 10)
   —C₆H₄CO(OCH₂CH₂)ₙ₅— (n5=1 to 10)

In Formula (4), R² is a hydrogen atom or a methyl group.

(b) Repeating unit having perfluoropolyether group

In Formula (F-1), it is also preferable that RF1 has a perfluoropolyether group.

The perfluoropolyether group is a divalent group in which a plurality of fluorocarbon groups are bonded through an ether bond. The perfluoropolyether group is preferably a divalent group in which a plurality of perfluoroalkylene groups are bonded through an ether bond.

The perfluoropolyether group may have a linear structure, a branched structure, or a cyclic structure, but preferably has the linear structure or the branched structure, and more preferably has the linear structure.

In a case where RF1 of Formula (F-1) includes a repeating unit containing a perfluoropolyether group, it is preferable that Formula (F-1) is a constitutional unit represented by Formula (I-b).

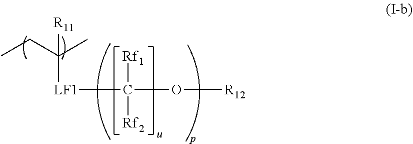

In Formula (I-b), LF1 represents the same group as that in Formula (F-1). Rn represents a hydrogen atom, a fluorine atom, a chlorine atom, or an alkyl group having 1 to 20 carbon atoms. Rf₁ and Rf₂ each independently represent a fluorine atom or a perfluoroalkyl group. In a case where a plurality of Rf₁'s are present, Rf₁'s may be the same as or different from each other. In a case where a plurality of Rf₂'s are present, Rf₂'s may be the same as or different from each other. u represents an integer of 1 or more. p represents an integer of 1 or more.

R₁₂ represents a hydrogen atom or a substituent, and the substituent is not particularly limited, but examples thereof include a fluorine atom, a perfluoroalkyl group (preferably having 1 to 10 carbon atoms), an alkyl group (preferably having 1 to 10 carbon atoms), and a hydroxyalkyl group (preferably having 1 to 10 carbon atoms).

In Formula (I-b), u represents an integer of 1 or more, preferably represents 1 to 10, more preferably represents 1 to 6, and still more preferably represents 1 to 3.

In Formula (I-b), p represents an integer of 1 or more, and preferably represents 1 to 100, more preferably represents 1 to 80, and still more preferably represents 1 to 60.

Furthermore, p pieces of [CRf₁Rf₂]uO's may be the same as or different from each other.

(c) Alkyl group having hydrogen bond between proton donor functional group and proton acceptor functional group, and having at least one carbon atom having fluorine atom as substituent and having 1 to 20 carbon atoms

In Formula (F-1), it is also preferable that RF1 has an alkyl group having a hydrogen bond between a proton donor functional group and a proton acceptor functional group, and having at least one carbon atom having a fluorine atom as a substituent and having 1 to 20 carbon atoms.

The compound having a proton-donor functional group and the compound having a proton-acceptor functional group is preferably a compound represented by any of Formulae (1-1) to (1-3).

(HB—X1)m-X3-(X2-RL)n (1-1)

(HB)—(X2-RL)n (1-2)

(HB—X1)m-(RL) (1-3)

In Formula (1-1) and Formula (1-3), m represents an integer of 1 to 5, and in Formula (1-1) and Formula (1-2), n represents an integer of 1 to 5. It should be noted that the sum of m and n represents an integer of 2 to 6.

In addition, in Formulae (1-1) to (1-3), HB represents the above-mentioned hydrogen-bondable functional group (that is, a proton-donating functional group and a proton-accepting functional group), and in a case where m is an integer of 2 to 5, the plurality of HB's may be the same as or different from each other.

Examples of the proton donor functional group include a carboxy group and a sulfonic acid group.

Examples of the proton acceptor functional group include a group including a nitrogen atom.

Moreover, in Formulae (1-1) to (1-3), X1 and X2 each independently represent a single bond or a divalent linking group; in a case where m is an integer of 2 to 5, the plurality of X1's may be the same as or different from each other; and in a case where n is an integer of 2 to 5, the plurality of X2's may be the same as or different from each other. Furthermore, in Formula (1-2), HB and X2 may form a ring together with a part of HB and X2, and in Formula (1-3), RL and X1 may form a ring together with a part of RL and X1.

Examples of the divalent linking group represented by one aspect of X1 and X2 in Formulae (1-1) to (1-3) include one or more groups selected from the group consisting of a linear, branched, or cyclic alkylene group having 1 to 10 carbon atoms, which may have a substituent, an arylene group having 6 to 12 carbon atoms, which may have a substituent, an ether group (—O—), a carbonyl group (—C(═O)—), and an imino group (—NH—) which may have a substituent.

Here, examples of the substituent which may be contained in the alkylene group, the arylene group, and the imino group include an alkyl group, an alkoxy group, a halogen atom, and a hydroxyl group. As the alkyl group, for example, a linear, branched, or cyclic alkyl group having 1 to 18 carbon atoms is preferable, an alkyl group having 1 to 8 carbon atoms (for example, a methyl group, an ethyl group, a propyl group, an isopropyl group, an n-butyl group, an isobutyl group, a sec-butyl group, a t-butyl group, and a cyclohexyl group) is more preferable, an alkyl group having 1 to 4 carbon atoms is still more preferable, and the methyl group or the ethyl group is particularly preferable. As the alkoxy group, for example, an alkoxy group having 1 to 18 carbon atoms is preferable, an alkoxy group having 1 to 8 carbon atoms (for example, a methoxy group, an ethoxy group, an n-butoxy group, and a methoxy ethoxy group) is more preferable, an alkoxy group having 1 to 4 carbon atoms is still more preferable, and the methoxy group or the ethoxy group is particularly preferable. Examples of the halogen atom include a fluorine atom, a chlorine atom, a bromine atom, and an iodine atom, and among those, the fluorine atom or the chlorine atom is preferable.

Specific examples of the linear, branched, or cyclic alkylene group having 1 to 10 carbon atoms, the linear alkylene group include a methylene group, an ethylene group, a propylene group, a butylene group, a pentylene group, a hexylene group, and a decylene group. Moreover, specific examples of the branched alkylene group include a dimethylmethylene group, a methylethylene group, a 2,2-dimethylpropylene group, and a 2-ethyl-2-methylpropylene group. In addition, specific examples of the cyclic alkylene group include a cyclopropylene group, a cyclobutylene group, a cyclopentylene group, a cyclohexylene group, a cyclooctylene group, a cyclodecylene group, an adamantane-diyl group, a norbornane-diyl group, and an exo-tetrahydrodicyclopentadiene-diyl group.

Specific examples of the arylene group having 6 to 12 carbon atoms include a phenylene group, a xylylene group, a biphenylene group, a naphthylene group, and a 2,2′-methylenebisphenyl group, and among these, the phenylene group is preferable.

In addition, in Formula (1-1), X3 represents a single bond or a divalent to hexavalent linking group. Here, examples of the divalent linking group represented by one aspect of X3 include those described as the divalent linking group represented by one aspect of X1 and X2 in Formulae (1-1) to (1-3). Further, examples of the trivalent to hexavalent linking group shown in one aspect of X3 include a structure obtained by removing 3 to 6 hydrogen atoms bonded to carbon atoms that form a ring in a ring structure, such as a cycloalkylene ring such as a cyclohexane ring and a cyclohexene ring; an aromatic hydrocarbon ring such as a benzene ring, a naphthalene ring, an anthracene ring, and a phenanthroline ring; and an aromatic heterocyclic ring such as a furan ring, a pyrrole ring, a thiophene ring, a pyridine ring, a thiazole ring, and a benzothiazole ring. Among these ring structures, the benzene ring (for example, a benzen-1,2,4-yl group) is preferable.

In addition, in Formulae (1-1) to (1-3), RL represents a substituent including a fluorine atom or an alkyl group having 6 or more carbon atoms, and in a case where n is an integer of 2 to 5, the plurality of RL's may be the same as or different from each other. Here, examples of the monovalent substituent including a fluorine atom include an alkyl group having 1 to 20 carbon atoms or an alkenyl group having 2 to 20 carbon atoms, in which at least one carbon atom has a fluorine atom as a substituent.

Among the compounds represented by any of Formulae (1-1) to (1-3), as the compound having a proton-donating functional group, specifically, for example, the compound represented by Formulae.

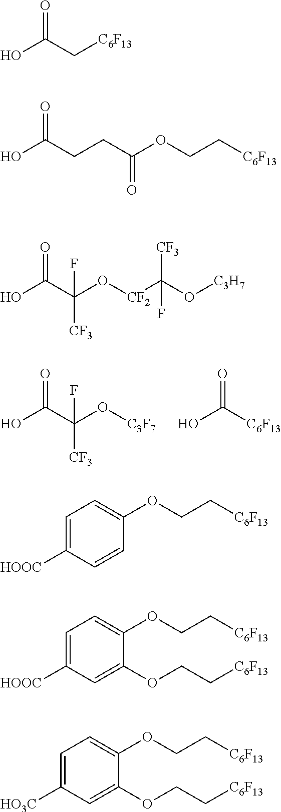

In addition, specific examples of the compound having a proton-acceptor functional group among the compounds represented by any of Formulae (1-1) to (1-3) include compounds represented by Formulae.

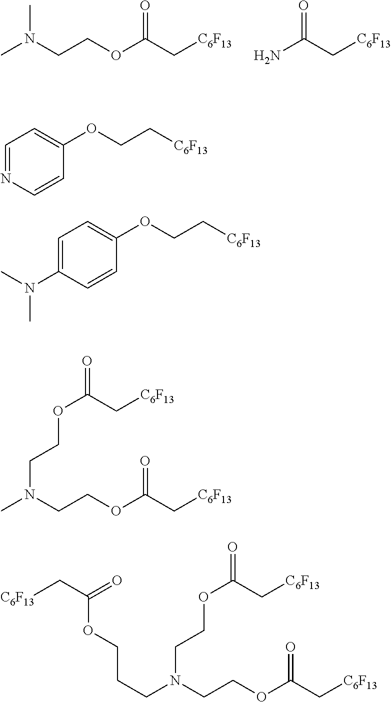

[Image Display Device]

An image display device of an embodiment of the present invention is an image display device having the optical film of the embodiment of the present invention or the polarizing plate of the embodiment of the present invention.

A display element used in the image display device of the embodiment of the present invention is not particularly limited, and examples thereof include a liquid crystal cell, an organic electroluminescent (hereinafter simply referred to as “EL”) display panel, and a plasma display panel.

Among those, the liquid crystal cell and the organic EL display panel are preferable, and the liquid crystal cell is more preferable. That is, as the image display device of the embodiment of the present invention, a liquid crystal display device using a liquid crystal cell as a display element or an organic EL display device using an organic EL display panel as a display element is preferable, and the liquid crystal display device is more preferable.

[Liquid Crystal Display Device]

A liquid crystal display device which is an example of the image display device of the embodiment of the present invention is a liquid crystal display device having the above-mentioned polarizing plate of the embodiment of the present invention and a liquid crystal cell.

In addition, in the present invention, it is preferable that the polarizing plate of the embodiment of the present invention is used as the polarizing plate of the front side, and it is more preferable that the polarizing plate of the embodiment of the present invention is used as the polarizing plates on the front and rear sides, among the polarizing plates provided on the both sides of the liquid crystal cell.

Hereinafter, the liquid crystal cell constituting the liquid crystal display device will be described in detail.

<Liquid Crystal Cell>

The liquid crystal cell used for the liquid crystal display device is preferably in a vertical alignment (VA) mode, an optically compensated bend (OCB) mode, an in-plane-switching (IPS) mode, a fringe-field-switching (FFS) mode, or a twisted nematic (TN) mode, but is not limited thereto.

In a TN-mode liquid crystal cell, rod-shaped liquid crystal molecules are substantially horizontally aligned and are twist-aligned at 600 to 120° during no voltage application thereto. A TN-mode liquid crystal cell is most often used in a color TFT liquid crystal display device and described in numerous documents.

In a VA-mode liquid crystal cell, rod-shaped liquid crystal molecules are substantially vertically aligned during no voltage application thereto. Examples of the VA-mode liquid crystal cell include (1) a VA-mode liquid crystal cell in the narrow sense of the word, in which rod-shaped liquid crystal molecules are substantially vertically aligned during no voltage application thereto, but are substantially horizontally aligned during voltage application thereto (described in JP1990-176625A (JP-H02-176625A)), (2) an MVA-mode liquid crystal cell in which the VA-mode is multi-domained for viewing angle enlargement (described in SID97, Digest of Tech. Papers (preprint), 28 (1997) 845), (3) a liquid crystal cell in a mode (n-ASM mode) in which rod-shaped liquid crystal molecules are substantially vertically aligned during no voltage application thereto and are twistedly multi-domain-aligned during voltage application thereto (described in Seminar of Liquid Crystals of Japan, Papers (preprint), 58-59 (1998)), and (4) a survival-mode liquid crystal cell (announced in LCD International 98). In addition, the liquid crystal cell may be of any of a patterned vertical alignment (PVA) type, an optical alignment type, and a polymer-sustained alignment (PSA). Details of these modes are specifically described in JP2006-215326A and JP2008-538819A.

In an IPS-mode liquid crystal cell, rod-shaped liquid crystal molecules are aligned substantially parallel with respect to a substrate, and application of an electric field parallel to the substrate surface causes the liquid crystal molecules to respond planarly. The IPS-mode displays black in a state where no electric field is applied and a pair of upper and lower polarizing plates have absorption axes which are orthogonal to each other. A method of improving the viewing angle by reducing light leak during black display in an oblique direction using an optical compensation sheet is disclosed in JP1998-54982A (JP-H10-54982A), JP1999-202323A (JP-H11-202323A), JP1997-292522A (JP-H09-292522A), JP1999-133408A (JP-H11-133408A), JP1999-305217A (JP-H11-305217A), JP1998-307291A (JP-H10-307291A), and the like.

[Organic EL Display Device]

Suitable examples of the organic EL display device which is an example of the image display device of the embodiment of the present invention include an aspect which includes, from the visible side, a polarizer, a V/4 plate (a positive A plate) including the optically anisotropic layer of the embodiment of the present invention, and an organic EL display panel in this order.

Furthermore, the organic EL display panel is a display panel composed of an organic EL device in which an organic light emitting layer (organic electroluminescent layer) is sandwiched between electrodes (between a cathode and an anode). The configuration of the organic EL display panel is not particularly limited but a known configuration is adopted.

### EXAMPLES

Hereinafter, the present invention will be described in more detail with reference to Examples. The materials, the amounts of materials used, the proportions, the treatment details, the treatment procedure, and the like shown in Examples below can be appropriately modified as long as the modifications do not depart from the spirit of the present invention. Therefore, the scope of the present invention should not be construed as being limited to Examples shown below.

### Example 1

[Manufacture of Protective Film 1]

<Preparation of Core Layer Cellulose Acylate Dope 1>

The following composition was put into a mixing tank and stirred to dissolve the respective components to prepare a core layer cellulose acylate dope 1.

Core layer cellulose acylate dope 1

| | |
|---|---|
| Cellulose acetate having a degree of | 100 parts by mass |
| acetyl substitution of 2.88 | |
| Ester oligomer (the following compound 1-1) | 10 parts by mass |
| Durability improver (the following compound 1-2) | 4 parts by mass |
| Ultraviolet absorber (the following compound 1-3) | 3 parts by mass |
| Methylene chloride (the first solvent) | 438 parts by mass |
| Methanol (the second solvent) | 65 parts by mass |

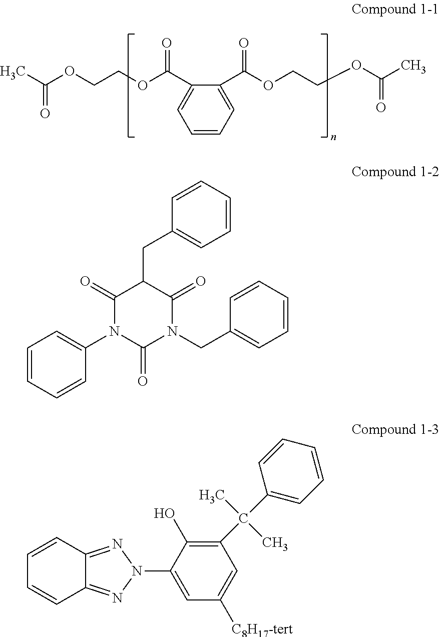

<Preparation of Outer Layer Cellulose Acylate Dope 1>

10 parts by mass of the following matting agent dispersion liquid 1 was added to 90 parts by mass of the core layer cellulose acylate dope 1 to prepare an outer layer cellulose acylate dope 1.

Matting agent solution

| | |
|---|---|
| Silica particles with an average particle size | 2 parts by mass |
| of 20 nm (AEROSIL R972, manufactured | |
| by Nippon Aerosil Co., Ltd.) | |
| Methylene chloride (the first solvent) | 76 parts by mass |
| Methanol (the second solvent) | 11 parts by mass |
| Core layer cellulose acylate dope 1 | 1 part by mass |

<Manufacture of Protective Film 1>

Three layers of the core layer cellulose acylate dope 1 and the outer layer cellulose acylate dopes 1 on both sides thereof were simultaneously casted from a casting port onto a drum at 20° C. In a state where a content of the solvent in the film on the drum was approximately 20% by mass, the film was peeled from the drum, and both ends of the obtained film in the width direction were fixed with tenter clips, and in a state where a content of the residual solvent in the film was 3% to 15% by mass, the film was stretched 1.2 times in the transverse direction and dried. Thereafter, the obtained film was transported between the rolls of a heat treatment device to manufacture a cellulose acylate film 1 with a thickness of 25 m, which was used as a protective film 1.

[Manufacture of Protective Film 1 with Hardcoat Layer]

As a coating liquid for forming a hardcoat layer, a curable composition (hardcoat 1) for a hardcoat shown in Table 4 below was prepared.

TABLE 4

| | Monomer | | | | UV initiator | | |
|---|---|---|---|---|---|---|---|
| | | | | Total addition | | Addition | |
| | | | Monomer 1/ | amount | | amount | |
| | Monomer 1 | Monomer 2 | monomer 2 | [parts by mass] | Type | [parts by mass] | Solvent |
| Hardcoat 1 | Pentaerythritol | Pentaerythritol | 3/2 | 53.5 | UV | 1.5 | Ethyl acetate |
| | triacrylate | tetraacrylate | | | initiator 1 | | |

The structure of a initiator in a e above is shown below.

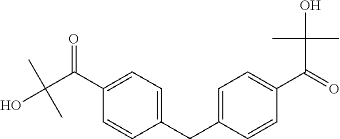 [SMILES: CC(C)(O)C(=O)c1ccc(Cc2ccc(C(=O)C(C)(C)O)cc2)cc1]

The curable composition 1 for hardcoat was applied onto a surface of the protective film 1 manufactured above, then dried at 100° C. for 60 seconds, irradiated with UV at 1.5 kW and 300 mJ under the conditions of 0.1% or less of nitrogen, and cured to manufacture a protective film 1 with a hardcoat layer, having a hardcoat layer with a film thickness of 5 m. Furthermore, the film thickness of the hardcoat layer was adjusted by adjusting a coating amount by a die coating method, using a slot die.

[Manufacture of Polarizing Plate 1 with Protective Film on One Surface]

(1) Saponification of Film

The manufactured protective film 1 with a hardcoat layer was immersed for 1 minute in a 4.5 mol/L aqueous sodium hydroxide solution (saponified solution) whose temperature had been adjusted to 37° C., and then the film was washed with water, then immersed in a 0.05 mol/L aqueous sulfuric acid solution for 30 seconds, and then further passed through a water washing bath. Then, the obtained film was repeatedly dehydrated three times with an air knife to drop water, and then the film was dried by leaving it in a drying zone at 70° C. for 15 seconds to manufacture a protective film 1 with a hardcoat layer, which had been saponified.

(2) Manufacture of Polarizer

According to Examples of JP2016-148724A, a polarizer with a film thickness of 15 m was prepared by providing a peripheral speed difference between two pairs of nip rolls and performing stretching in the longitudinal direction. The polarizer thus manufactured was used as a polarizer 1.

(3) Bonding

The polarizer 1 thus obtained and the protective film 1 with a hardcoat layer which had been subjected to the saponification treatment were bonded in a roll-to-roll manner so that the polarizing axis and the longitudinal direction of the film are orthogonal to each other, using a 3% aqueous PVA solution (manufactured by Kuraray Co., Ltd., PVA-117H) as an adhesive, thereby forming a polarizing plate 1 with a protective film on one surface thereof (hereinafter also simply referred to as a “polarizing plate 1”). At this time, the bonding was performed so that the cellulose acylate film side of the protective film was on the polarizer side.

[Manufacture of Polarizing Plate 2 with Protective Film on One Surface]

A polarizing plate 2 with a protective film on one surface (hereinafter also simply referred to as a “polarizing plate 2”) was manufactured in the same manner as in the manufacture of the polarizing plate 1, except that a hardcoat layer was not provided on a surface of the protective film 1. Furthermore, each liquid crystal display device was manufactured, using the polarizing plate 1 on a visible side and the polarizing plate 2 on a backlight side, in particular, unless otherwise specified in the following Examples and Comparative Examples.

[Manufacture of Protective Film 2]

<Manufacture of Core Layer Cellulose Acylate Dope 2>

The following composition was put into a mixing tank and stirred to dissolve the respective components to prepare a core layer cellulose acylate dope 2.

Core layer cellulose acylate dope 2

| | |
|---|---|
| Cellulose acetate having a degree of acetyl | 100 parts by mass |
| substitution of 2.88 | |
| The following polyester | 12 parts by mass |
| The durability improver (the compound 1-2) | 4 parts by mass |
| Methylene chloride (the first solvent) | 430 parts by mass |
| Methanol (the second solvent) | 64 parts by mass |

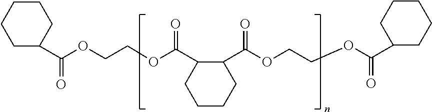

<Manufacture of Outer Layer Cellulose Acylate Dope 2>

10 parts by mass of the following matting agent solution was added to 90 parts by mass of the core layer cellulose acylate dope 2 to prepare an outer layer cellulose acylate dope 2.

Matting agent solution

| | |
|---|---|
| Silica particles with an average particle | 2 parts by mass |
| size of 20 nm (AEROSIL R972, | |
| manufactured by Nippon Aerosil Co., Ltd.) | |
| Methylene chloride (the first solvent) | 76 parts by mass |
| Methanol (the second solvent) | 11 parts by mass |
| Core layer cellulose acylate dope | 1 part by mass |

<Manufacture of Protective Film 2>

The core layer cellulose acylate dope 2 and the outer layer cellulose acylate dope 2 were filtered through a filter paper with an average pore diameter of 34 m and a sintered metal filter with an average pore diameter of 10 m, and then all of the three layers of the core layer cellulose acylate dope 2 and the outer layer cellulose acylate dopes 2 on both sides thereof were simultaneously cast on a drum at 20° C. from a casting port (band casting machine).

Subsequently, the film was peeled from the drum in a state where a content of the solvent of the film on the drum reached approximately 20% by mass, the both ends of the film in the width direction were fixed with tenter clips, and the film was dried while being stretched at a stretching ratio of 1.1 times in the transverse direction.

Thereafter, the obtained film was transported between the rolls of a heat treatment device and further dried to manufacture a cellulose acylate film 2 with a film thickness of 40 m, which was used as a protective film 2.

Furthermore, as a result of the measurement of the phase difference of the protective film 2, Re=1 nm and Rth=−5 nm were obtained.

[Manufacture of First Optically Anisotropic Layer]

<Preparation of Composition 1 for Photo-Alignment Film>

The photoalignment film forming material described in Example 1 of WO2016/002722A was prepared and used for producing the optical film of the embodiment of the present invention.

<Preparation of Composition for Forming Optically Anisotropic Layer>

A composition 1 for forming an optically anisotropic layer having the following composition was prepared.

Composition 1 for forming an optically anisotropic layer

| | |
|---|---|
| The following liquid crystal compound R1 | 42.00 parts by mass |
| The following liquid crystal compound R2 | 42.00 parts by mass |
| The following polymerizable compound A1 | 12.00 parts by mass |
| The following polymerizable compound A2 | 4.00 parts by mass |
| The following polymerization initiator S1 | 0.50 parts by mass |
| The following leveling agent P1 | 0.23 parts by mass |
| HISOLVE MTEM (manufactured by | 2.00 parts by mass |
| Toho Chemical Industry Co., Ltd.) | |
| NK ESTER A-200 (manufactured by Shin | 1.00 part by mass |
| Nakamura Chemical Co., Ltd.) | |
| Methyl ethyl ketone | 424.8 parts by mass |

Furthermore, a group adjacent to the acryloyloxy group of each of the following liquid crystal compounds R1 and R2 represents a propylene group (a group obtained by substituting a methyl group with an ethylene group), and the following liquid crystal compounds R1 and R2 each represent a mixture of regioisomers having different positions of the methyl groups.

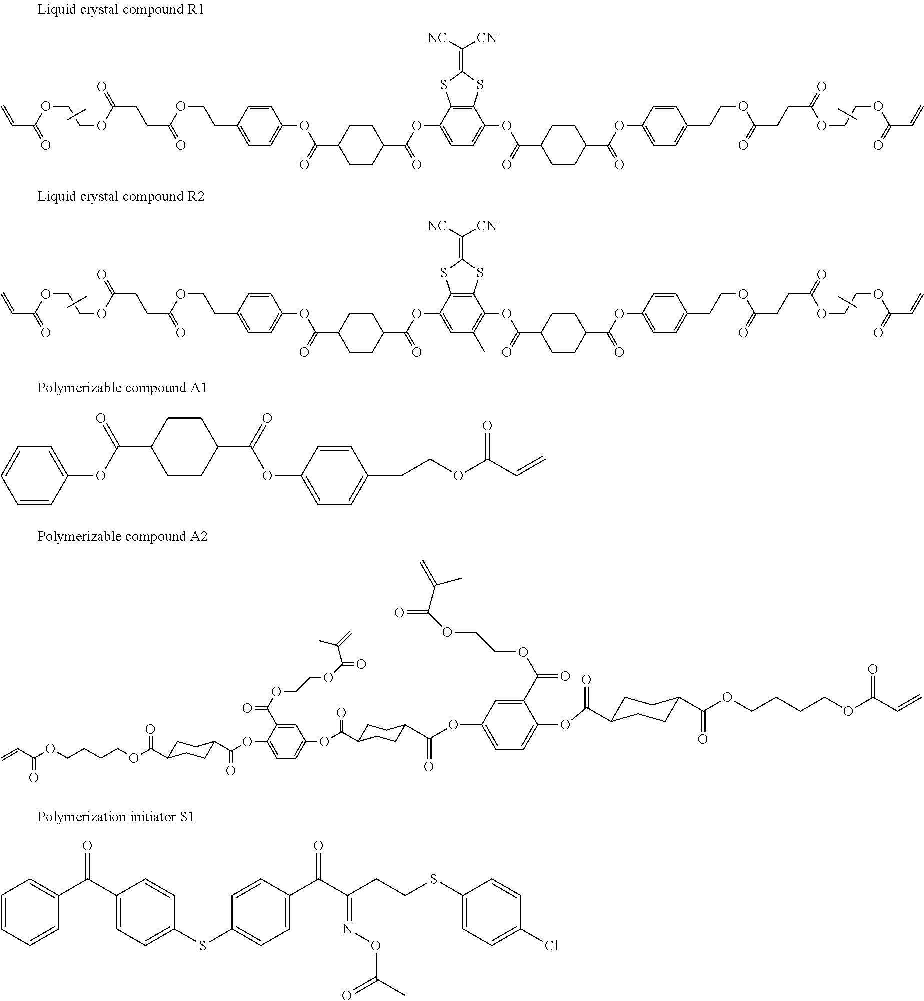

Leveling Agent P1

(In Formulae, a to c satisfy a:b:c=40:50:10, and represent contents (% by mole) of the respective repeating unit with respect to all repeating units in the resin.)

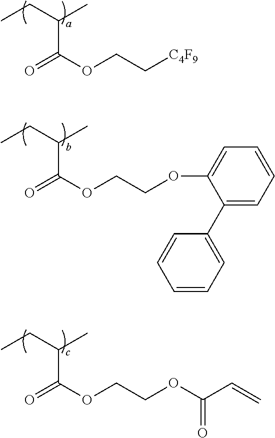

<Manufacture of First Optically Anisotropic Layer>

The photo-alignment film forming material prepared above was applied onto one surface of the manufactured protective film 2 under the condition of a transport speed of 30 m/min by a die coating method, using the slot die described in Example 1 of JP2006-122889A, and dried at 120° C. for 1 minute to remove the solvent. Thereafter, the film was irradiated with polarized ultraviolet rays (10 mJ/cm², using an ultra-high-pressure mercury lamp), to form a photo-alignment film 1 with a thickness of 0.3 m.

Subsequently, the composition 1 for forming an optically anisotropic layer prepared above was applied onto the photo-alignment film 1 with a spin coater so that the film thickness after drying was 2.5 m. After the application, the film was heated for 30 seconds in a temperature range indicating the liquid crystal state of a nematic phase, cooled to a temperature 10° C. lower than a phase transition temperature from the nematic phase to a smectic phase, and then irradiated with UV (300 mJ/cm²) at the temperature to manufacture a first optically anisotropic layer in which a liquid crystal state of a smectic phase (Sm) is immobilized.

[Manufacture of Second Optically Anisotropic Layer]

The surface on the coated side of the first optically anisotropic layer was subjected to a corona treatment at a discharge amount of 150 W min/m², and the composition 2 for forming the optically anisotropic layer prepared with the following composition was applied onto the surface which had been subjected to the corona treatment, using a wire bar.

Subsequently, heating was performed with warm air at 70° C. for 90 seconds in order to dry the solvent of the composition and subject the liquid crystal compound to alignment-aging. Under a nitrogen purge, ultraviolet irradiation (300 mJ/cm²) was performed at an oxygen concentration of 0.1% at 40° C., and the alignment of the liquid crystal compound was immobilized to manufacture a second optically anisotropic layer on the first optically anisotropic layer, thereby obtaining an optical film 1.

Furthermore, the layer structure of the optical film 1 is a layer structure including the protective film 2, the photoalignment film 1, the first optically anisotropic layer, and the second optically anisotropic layer in this order.

In addition, the thickness-direction retardation Rth2(550) and the Rth2(450)/Rth2(550) of the obtained second optically anisotropic layer were −100 nm and 0.95, respectively.

In addition, the wavelength dispersibility of the obtained optical film 1, that is, Re(450)/Re(550) was 0.86.

Composition 2 for forming an optically anisotropic layer

| | |
|---|---|
| The liquid crystal compound R1 | 10.0 parts by mass |
| The liquid crystal compound R2 | 54.0 parts by mass |
| The following liquid crystal compound R3 | 28.0 parts by mass |
| The polymerizable compound A2 | 8.0 parts by mass |
| The following compound B1 | 4.5 parts by mass |
| Monomer K1 (A-600, manufactured by Shin | 8.0 part by mass |
| Nakamura Chemical Co., Ltd.) | |
| The polymerization initiator S1 | 3.0 parts by mass |
| The following leveling agent P2 | 0.4 parts by mass |
| The following leveling agent P3 | 0.5 parts by mass |
| Methyl ethyl ketone | 175.0 parts by mass |
| Cyclopentanone | 75.0 parts by mass |
| Methanol | 12.5 parts by mass |
| Isopropanol | 12.5 parts by mass |

Liquid Crystal Compound R3

A mixture of the following liquid crystal compounds (RA), (RB), and (RC) at a ratio of 83:15:2 (mass ratio)

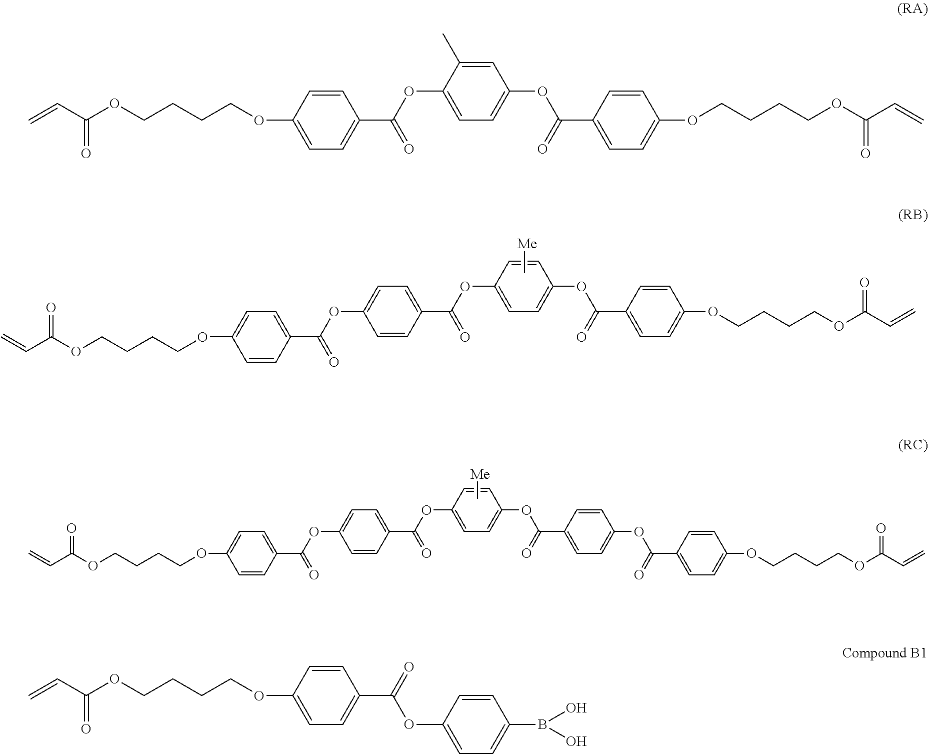

Leveling agent P2 (weight-average molecular weight: 15,000, the numerical value in the following formula is % by mass)

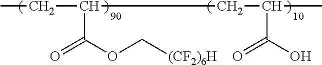

Leveling agent P3 (weight-average molecular weight: 11,200)

(In Formulae, a to d satisfy a:b:c:d=56:10:29:5, and represent contents (% by mole) of the respective repeating unit with respect to all repeating units in the resin.)

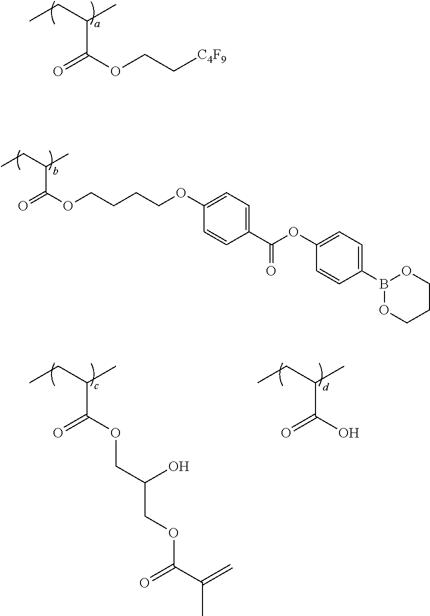

[Manufacture of First Polarizing Plate]

<Preparation of Adhesive Composition 1-1>

The following compounds were mixed in the ratio described to prepare an adhesive composition 1-1.

Polymerizable compound (CELLOXIDE 2021P, manufactured by Daicel Corporation): 65.4 parts by mass

Polymerizable compound (Rica Resin DME100, manufactured by New Japan Chemical Co., Ltd.): 18.7 parts by mass

Polymerizable compound (2-Ethylhexyl glycidyl ether, manufactured by Tokyo Chemical Industry Co., Ltd.): 9.3 parts by mass

Polymerization initiator (Irgacure 290, BASF Japan Ltd.): 3.7 parts by mass

Sensitizer (Isopropylthioxanthone, manufactured by Tokyo Chemical Industry Co., Ltd.): 0.9 parts by mass

<Manufacture of First Polarizing Plate>

A surface of the manufactured optical film 1 on the side of the second optically anisotropic layer was subjected to a corona treatment with a discharge amount of 150 W min/m², and then the adhesive composition 1-1 was applied thereonto to a film thickness of 3.0 m, thereby forming an adhesive layer.

Thereafter, the adhesive-coated surface was bonded to the polarizer surface of the polarizing plate 1 with a single-sided protective film, and irradiated with ultraviolet rays of 300 mJ/cm² from the substrate side of the laminate at room temperature in an air atmosphere to manufacture a first polarizing plate of Example 1.

[Manufacture of Protective Film 3]

<Manufacture of Polymethyl Methacrylate (PMMA) Dope>

The following dope composition was put into a mixing tank and stirred to dissolve each component to prepare a PMMA dope.

PMMA Dope

| | |
|---|---|
| PMMA resin | 100 parts by mass |
| Sumilizer GS (manufactured by | 0.1 parts by mass |
| Sumitomo Chemical Co., Ltd.) | |
| Dichloromethane | 426 parts by mass |
| Methanol | 64 parts by mass |

<Manufacture of Protective Film 3>

The above-mentioned PMMA dope was uniformly cast on a stainless steel-made band (casting support) from a casting die (band casting machine). The film was peeled in a state where the solvent content in the cast film was approximately 20% by mass, and the both ends of the film in the width direction were fixed with tenter clips and dried while the film was stretched at a stretching ratio of 1.1 times in the transverse direction. Thereafter, the obtained film was transported between the rolls of a heat treatment device and further dried to manufacture a PMMA film with a film thickness of 20 m, which was used as a protective film 3.

[Manufacture of Second Polarizing Plate]

<Preparation of Adhesive Composition 2>

The following compounds were mixed in the ratio described to prepare an adhesive composition 2.

Polymerizable compound (ARONIX M-220, manufactured by Toagosei Co., Ltd.): 20 parts by mass

4-Hydroxybutyl acrylate (manufactured by Nihon Kasei Co., Ltd.): 40 parts by mass

Polymerizable compound (2-Ethylhexyl acrylate, manufactured by Mitsubishi Chemical Corporation): 40 parts by mass

Polymerizable initiator (Irgacure 907, manufactured by BASF): 1.5 parts by mass

Sensitizer (KAYACURE DETX-S, manufactured by Nippon Kayaku Co., Ltd.): 0.5 parts by mass

<Manufacture of Second Polarizing Plate>

The polarizer-bonded surface of the protective film 3 was subjected to a corona treatment with a discharge amount of 150 W min/m², and then the adhesive composition 2 was coated so as to have a film thickness of 0.5 m.

Then, the adhesive-coated surface was bonded to the polarizer surface of the polarizing plate 2 with a protective film on one surface, and irradiated with ultraviolet rays from the base material side of the protective film 3 at 300 mJ/cm² at 40° C. in an air atmosphere. Thereafter, the resultant was dried at 60° C. for 3 minutes to manufacture a second polarizing plate of Example 1.

[Manufacture of Liquid Crystal Display Device]

Polarizing plates on the front and back surfaces from a commercially available liquid crystal display device (iPad (registered trademark), manufactured by Apple Inc.) (liquid crystal display device including a liquid crystal cell in an FFS mode) were peeled, and thus, the first polarizing plate including the first optically anisotropic layer 1 and the second optically anisotropic layer 1 manufactured above was bonded on the viewing side and the second polarizing plate was bonded on a backlight side with a 20 m acrylic pressure sensitive adhesive so that the alignment direction of the liquid crystal in the liquid crystal cell was orthogonal to the absorption axis of the polarizer in the first polarizing plate, thereby manufacturing a liquid crystal display device of Example 1.

Furthermore, the liquid crystal cell in the liquid crystal display device includes a color filter layer on the substrate on the first polarizing plate side and the TFT layer on the substrate on the second polarizing plate side, and the Rth(550) of both the layers were 10 nm and 2 nm, respectively. In addition, An d of the liquid crystal compound in the liquid crystal cell was 340, and the tilt angle of the liquid crystal compound with respect to the substrate surface was 0.10.

### Example 2

An adhesive composition 1-2 was prepared by the same method as for the adhesive composition 1-1, except that a polymerization initiator (CPI-300, manufactured by San-Apro Ltd.) was used instead of the polymerization initiator (Irgacure 290, BASF Japan Ltd.).

Next, a first polarizing plate and a liquid crystal display device were manufactured by the same method as in Example 1, except that the adhesive composition 1-2 was used instead of the adhesive composition 1-1.

### Example 3

A first polarizing plate was manufactured by the method shown below.

In addition, a liquid crystal display device was manufactured in the same manner as in Example 1, except that the first polarizing plate manufactured by a method shown below was used.

[Manufacture of First Polarizing Plate]

<Preparation of Adhesive Composition 1-3>

The following compounds were mixed in the ratio described to prepare an adhesive composition 1-3.

Polymerizable compound (ARONIX M-220, manufactured by Toagosei Co., Ltd.): 20 parts by mass

4-Hydroxybutyl acrylate (manufactured by Nihon Kasei Co., Ltd.): 40 parts by mass

Polymerizable compound (2-Ethylhexyl acrylate, manufactured by Mitsubishi Chemical Corporation): 40 parts by mass

The polymerization initiator Si: 1.5 parts by mass

Sensitizer (KAYACURE DETX-S, manufactured by Nippon Kayaku Co., Ltd.): 0.5 parts by mass

<Manufacture of First Polarizing Plate>

A surface of the produced optical film 1 on the side of the second optically anisotropic layer was subjected to a corona treatment with a discharge amount of 150 W min/m², and then the adhesive composition 1-2 was applied thereonto to a film thickness of 0.5 m.

Then, the adhesive-coated surface was bonded to the polarizer surface of the polarizing plate 1 with a protective film on one surface, and irradiated with ultraviolet rays from the laminate side at 300 mJ/cm² at 40° C. in an air atmosphere. Thereafter, the resultant was dried at 60° C. for 3 minutes to manufacture a first polarizing plate of Example 2.

### Examples 4 to 10

A first polarizing plate and a liquid crystal display device were manufactured by the same method as in Example 1, except that the liquid crystal compound used for forming the first optically anisotropic layer and the second optically anisotropic layer was changed to a liquid crystal compound shown in Table 5 below.

### Example 11

A composition 3 for forming an optically anisotropic layer was prepared by the same method as in Example 1, except that the leveling agent P3 was not blended.

A first polarizing plate and a liquid crystal display device were manufactured by the same method as in Example 1, except that the composition 3 for forming an optically anisotropic layer was used instead of the composition 2 for forming an optically anisotropic layer.

### Example 12

A first polarizing plate and a liquid crystal display device were manufactured by the same method as in Example 1, except that the first optically anisotropic layer was immobilized in a liquid crystal state of a nematic (Nm) phase.

### Example 13

An adhesive composition 1-4 was prepared by the same method as for the adhesive composition 1-1, except that a sensitizer (Isopropylthioxanthone, manufactured by Tokyo Chemical Industry Co., Ltd.) was not blended.

Next, a first polarizing plate and a liquid crystal display device were manufactured by the same method as in Example 1, except that the adhesive composition 1-4 was used instead of the adhesive composition 1-1.

### Comparative Example 1

A first polarizing plate and a liquid crystal display device were manufactured by the same method as in Example 1, except that the adhesive composition 2 used for manufacturing the second polarizing plate was used instead of the adhesive composition 1-1 as the adhesive composition used for manufacturing the first polarizing plate.

### Comparative Example 2

An adhesive composition 1-5 was prepared by the same method as for the adhesive composition 1-1, except that a polymerization initiator (CPI-100P, manufactured by San-Apro Ltd.) was used instead of the polymerization initiator (Irgacure 290, BASF Japan Ltd.).

Next, a first polarizing plate and a liquid crystal display device were manufactured by the same method as in Example 1, except that the adhesive composition 1-5 was used instead of the adhesive composition 1-1.

### Comparative Example 3

An adhesive composition 1-6 was prepared by the same method as for the adhesive composition 1-1, except that a polymerization initiator (MOP-Triazine, manufactured by Sanwa Chemical Co., Ltd.) was used instead of the polymerization initiator (Irgacure 290, BASF Japan Ltd.).

Next, a first polarizing plate and a liquid crystal display device were manufactured by the same method as in Example 1, except that the adhesive composition 1-6 was used instead of the adhesive composition 1-1.

### Reference Example 1

A first polarizing plate and a liquid crystal display device were manufactured by the same method as in Example 1, except that the liquid crystal compound used for forming the first optically anisotropic layer and the second optically anisotropic layer was changed to a liquid crystal compound shown in Table 6 below.

### Evaluation

The first polarizing plate and the liquid crystal display device manufactured in Examples 1 to 13, Comparative Examples 1 to 3, and Reference Example 1 were evaluated as shown below. Furthermore, in Examples 1 to 10 and 12 to 13, it was confirmed by the method described above that the leveling agent P3 was present on a surface of the second optically anisotropic layer on the adhesive layer side.

[Evaluation of Liquid Crystal Display Device]

<Front Surface CR>

A black brightness and a white brightness were measured using a measuring device (EZ-Contrast XL88, manufactured by ELDIM) during the black display of a liquid crystal display device in a dark room. With CR=[White brightness]/[Black brightness], evaluation was performed according to the following standard. The results are shown in Tables 5 and 6 below.
A: CR≥900
B: 700≤CR<900
C: CR<700

<Oblique Light Leak>

A black brightness was measured using a measuring device (EZ-Contrast XL88, manufactured by ELDIM) during the black display of a liquid crystal display device in a dark room. With an average value of the brightness at azimuth angles of 45°, 135°, 225°, and 3150 at a polar angle of 600 defined as a light leak Y, evaluation was performed according to the following standard. The results are shown in Tables 5 and 6 below. Furthermore, with regard to the azimuth angle, the azimuthal angle was defined such that an absorption axis direction of the polarizer (first polarizer) on the viewing side is 0° (and 180°) and the absorption axis direction of the polarizer (second polarizer) on the backlight side is 900 (and 270°).
A: Y<0.6 (cd/m²)
B: 0.6 (cd/m²)≤Y<0.8 (cd/m²)
C: 0.8 (cd/m²)≤Y

[Evaluation of First Polarizing Plate]

<Adhesiveness>

The manufactured first polarizing plate was cut into a length of 150 mm×25 mm in the absorption axis direction of the polarizer, and only the 80 mm×25 mm portion was bonded to a glass substrate through an adhesive (SK1478, manufactured by Soken Kagaku Co., Ltd.). The peel strength at the time of peeling in the 900 direction was measured with a Tensilon universal material tester (manufactured by Orientec Co., Ltd.) and evaluated according to the following standard. The results are shown in Tables 5 and 6 below.
(Evaluation Standard)
A: 3.0 N/25 mm or more
B: 1.0 N/25 mm or more and less than 3.0 N/25 mm
C: Less than 1.0 N/25 mm

<Durability>

The manufactured first polarizing plate was cut into a polarizer of 400 mm×400 mm, bonded to a glass substrate through an adhesive (SK-2057, manufactured by Soken Kagaku Co., Ltd.), and the degree of polarization P after being held at 65° C. for 500 hours was measured with VAP-7070 (manufactured by JASCO Corporation) and evaluated according to the following standard. The results are shown in Tables 5 and 6 below.
(Evaluation Standard)
A: P≥99%
B: 90%≤P<99%
C: P<90%

TABLE 5

| | Optical Film | | | | | | | |
|---|---|---|---|---|---|---|---|---|
| | | | Liquid crystal | Liquid crystal | | | | |
| | | | compound used | compound used | | | | |
| | | | for forming | for forming | | Wavelength | | Polymer |
| | | | first | second | Minimum | (nm) with | First | present on |
| | | | optically | optically | absorption | transmittance | optically | surface on |
| | Re(450)/ | Re(650)/ | anisotropic | anisotropic | wavelength | of 1% or | anisotropic | adhesive |
| | Re(550) | Re(550) | layer | layer | (nm) | more | layer | layer side |
| Example 1 | 0.86 | 1.03 | Liquid crystal | Liquid crystal | 300 | ≥380 | Sm phase | Leveling |
| | | | compound R [symbol] | compound R [symbol] | | | | agent P3 |
| | | | Liquid crystal | Liquid crystal | | | | |
| | | | compound R2 | compound R2 | | | | |
| | | | | Liquid crystal | | | | |
| | | | | compound R3 | | | | |
| Example 2 | 0.86 | 1.03 | Liquid crystal | Liquid crystal | 300 | ≥380 | Sm phase | Leveling |
| | | | compound R [symbol] | compound R [symbol] | | | | agent P3 |
| | | | Liquid crystal | Liquid crystal | | | | |
| | | | compound R2 | compound R2 | | | | |
| | | | | Liquid crystal | | | | |
| | | | | compound R3 | | | | |
| Example 3 | 0.86 | 1.03 | Liquid crystal | Liquid crystal | 300 | ≥380 | Sm phase | Leveling |
| | | | compound R [symbol] | compound R [symbol] | | | | agent P3 |
| | | | Liquid crystal | Liquid crystal | | | | |
| | | | compound R2 | compound R2 | | | | |
| | | | | Liquid crystal | | | | |
| | | | | compound R3 | | | | |
| Example 4 | 0.86 | 1.03 | Liquid crystal | Liquid crystal | 300 | ≥380 | Sm phase | Leveling |
| | | | compound R4 | compound R4 | | | | agent P3 |
| | | | | Liquid crystal | | | | |
| | | | | compound R3 | | | | |
| Example 5 | 0.86 | 1.03 | Liquid crystal | Liquid crystal | 300 | ≥380 | Sm phase | Leveling |
| | | | compound R5 | compound R5 | | | | agent P3 |
| | | | | Liquid crystal | | | | |
| | | | | compound R3 | | | | |
| Example 6 | 0.86 | 1.03 | Liquid crystal | Liquid crystal | 300 | ≥380 | Sm phase | Leveling |
| | | | compound R6 | compound R6 | | | | agent P3 |
| | | | | Liquid crystal | | | | |
| | | | | compound R3 | | | | |
| Example 7 | 0.86 | 1.03 | Liquid crystal | Liquid crystal | 300 | ≥380 | Sm phase | Leveling |
| | | | compound R7 | compound R7 | | | | agent P3 |
| | | | | Liquid crystal | | | | |
| | | | | compound R3 | | | | |
| Example 8 | 0.86 | 1.03 | Liquid crystal | Liquid crystal | 300 | ≥380 | Sm phase | Leveling |
| | | | compound R8 | compound R8 | | | | agent P3 |
| | | | | Liquid crystal | | | | |
| | | | | compound R3 | | | | |
| Example 9 | 0.86 | 1.03 | Liquid crystal | Liquid crystal | 300 | ≥380 | Sm phase | Leveling |
| | | | compound R9 | compound R9 | | | | agent P3 |
| | | | | Liquid crystal | | | | |
| | | | | compound R3 | | | | |
| Example 10 | 0.86 | 1.03 | Liquid crystal | Liquid crystal | 300 | ≥380 | Sm phase | Leveling |
| | | | compound R10 | compound R10 | | | | agent P3 |
| | | | | Liquid crystal | | | | |
| | | | | compound R3 | | | | |

| | Adhesive composition used for | | | | | | | |
|---|---|---|---|---|---|---|---|---|
| | manufacturing first polarizing plate | | | | | | | |
| | | Maximum | | | | | | |
| | | absorption | Molar | Maximum | Evaluation | | | |
| | | wavelength | absorption | absorption | Front | | | |
| | | (nm) of | coefficient of | wavelength | surface | Oblique | | |
| | Polymerizable | polymerization | polymerization | (nm) of | CR | light leak | Adhe- | Dura- |
| | compound | initiator | initiator | sensitizer | implemented | implemented | siveness | bility |
| Example 1 | Epoxy | 320 | Irgacore 290 | 382 | A | A | A | A |
| | | | 75000 | | | | | |
| Example 2 | Epoxy | 285 | CPI-300 | 382 | A | A | A | A |
| | | | [symbol] | | | | | |
| Example 3 | Acryl | 26 [symbol] | Polymerization | 382 | A | A | A | A |
| | | | initiator [symbol] | | | | | |
| | | | [symbol] | | | | | |
| Example 4 | Epoxy | 320 | Irgacore 290 | 382 | A | A | A | A |
| | | | 7 [symbol] | | | | | |
| Example 5 | Epoxy | 320 | Irgacore 290 | 382 | A | A | A | A |
| | | | 7 [symbol] | | | | | |
| Example 6 | Epoxy | 320 | Irgacore 290 | 382 | A | A | A | A |
| | | | 75 [symbol] | | | | | |
| Example 7 | Epoxy | 320 | Irgacore 290 | 382 | A | A | A | A |
| | | | 75000 | | | | | |
| Example 8 | Epoxy | 320 | Irgacore 290 | 382 | A | A | A | A |
| | | | 75000 | | | | | |
| Example 9 | Epoxy | 320 | Irgacore 290 | 382 | A | A | A | A |
| | | | 75000 | | | | | |
| Example 10 | Epoxy | 320 | Irgacore 290 | 382 | A | A | A | A |
| | | | 75000 | | | | | |

[symbol]

indicates data missing or illegible when filed

TABLE 6

| | Optical Film | | | | | | | |
|---|---|---|---|---|---|---|---|---|
| | | | Liquid crystal | Liquid crystal | | | | |
| | | | compound used | compound used | | | | |
| | | | for forming | for forming | | Wavelength | | Polymer |
| | | | first | second | Minimum | (nm) with | First | present on |
| | | | optically | optically | absorption | transmittance | optically | surface on |
| | Re(450)/ | Re(650)/ | anisotropic | anisotropic | wavelength | of 1% or | anisotropic | adhesive |
| | Re(550) | Re(550) | layer | layer | (nm) | more | layer | layer side |
| Example 11 | 0.86 | 1.03 | Liquid crystal | Liquid crystal | 300 | ≥380 | Sm phase | None |
| | | | compound R1 | compound R [symbol] | | | | |
| | | | Liquid crystal | Liquid crystal | | | | |
| | | | compound R2 | compound R2 | | | | |
| | | | | Liquid crystal | | | | |
| | | | | compound R3 | | | | |
| Example 12 | 0.86 | 1.03 | Liquid crystal | Liquid crystal | 300 | ≥380 | Ne phase | Leveling |
| | | | compound R1 | compound R [symbol] | | | | agent P3 |
| | | | Liquid crystal | Liquid crystal | | | | |
| | | | compound R2 | compound R2 | | | | |
| | | | | Liquid crystal | | | | |
| | | | | compound R3 | | | | |
| Example 13 | 0.86 | 1.03 | Liquid crystal | Liquid crystal | 300 | ≥380 | Sm phase | Leveling |
| | | | compound R1 | compound R [symbol] | | | | agent P3 |
| | | | Liquid crystal | Liquid crystal | | | | |
| | | | compound R2 | compound R2 | | | | |
| | | | | Liquid crystal | | | | |
| | | | | compound R3 | | | | |
| Comparative | 0.86 | 1.03 | Liquid crystal | Liquid crystal | 300 | ≥380 | Sm phase | Leveling |
| Example 1 | | | compound R1 | compound R [symbol] | | | | agent P3 |
| | | | Liquid crystal | Liquid crystal | | | | |
| | | | compound R2 | compound R2 | | | | |
| | | | | Liquid crystal | | | | |
| | | | | compound R3 | | | | |
| Comparative | 0.86 | 1.03 | Liquid crystal | Liquid crystal | 300 | ≥380 | Sm phase | Leveling |
| Example 2 | | | compound R1 | compound R [symbol] | | | | agent P3 |
| | | | Liquid crystal | Liquid crystal | | | | |
| | | | compound R2 | compound R2 | | | | |
| | | | | Liquid crystal | | | | |
| | | | | compound R3 | | | | |
| Comparative | 0.86 | 1.03 | Liquid crystal | Liquid crystal | 300 | ≥380 | Sm phase | Leveling |
| Example 3 | | | compound R1 | compound R [symbol] | | | | agent P3 |
| | | | Liquid crystal | Liquid crystal | | | | |
| | | | compound R2 | compound R2 | | | | |
| | | | | Liquid crystal | | | | |
| | | | | compound R3 | | | | |
| R [symbol] | [symbol] .0 [symbol] | 0.99 | Liquid crystal | Liquid crystal | — | ≥380 | Ne phase | Leveling |
| Example 1 | | | compound R20 | compound R20 | | | | agent P3 |

| | Adhesive composition used for | | | | | | | |
|---|---|---|---|---|---|---|---|---|
| | manufacturing first polarizing plate | | | | | | | |
| | | Maximum | | | | | | |
| | | absorption | Molar | Maximum | Evaluation | | | |
| | | wavelength | absorption | absorption | Front | | | |
| | | (nm) of | coefficient of | wavelength | surface | Oblique | | |
| | Polymerizable | polymerization | polymerization | (nm) of | CR | light leak | Adhe- | Dura- |
| | compound | initiator | initiator | sensitizer | implemented | implemented | siveness | bility |
| Example 11 | Epoxy | 320 | Irgacore 290 | 382 | A | A | B | A |
| | | | 75000 | | | | | |
| Example 12 | Epoxy | 320 | Irgacore 290 | 382 | B | A | A | A |
| | | | 75000 | | | | | |
| Example 13 | Epoxy | 320 | Irgacore 290 | Not added | A | A | A | B |
| | | | 75000 | | | | | |
| Comparative | Acryl | 310 | Irgacore [symbol] | 382 | A | A | C | C |
| Example 1 | | | 21500 | | | | | |
| Comparative | Epoxy | 310 | CPI-100P | Not added | A | A | C | C |
| Example 2 | | | 18000 | | | | | |
| Comparative | Epoxy | 3 [symbol] | MOP-Triazine | Not added | A | A | C | C |
| Example 3 | | | 34000 | | | | | |
| R [symbol] | Epoxy | 320 | Irgacore 290 | 382 | B | C | A | A |
| Example 1 | | | 75000 | | | | | |

[symbol]

indicates data missing or illegible when filed

The structures of the liquid crystal compounds in Tables 5 and 6 are shown below.

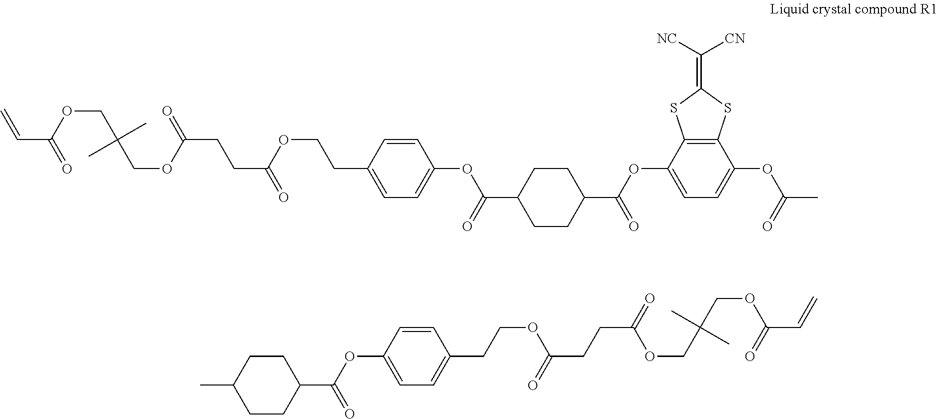

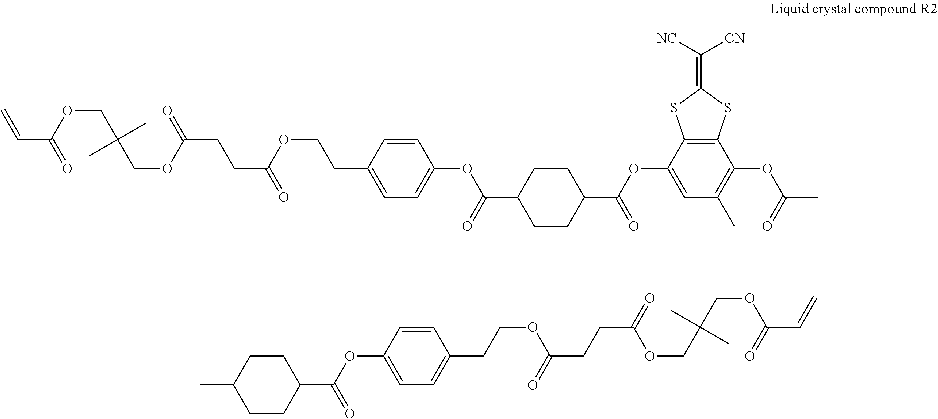

A mixture of the following liquid crystal compounds (RA), (RB), and (RC) at a ratio of 83:15:2 (mass ratio)

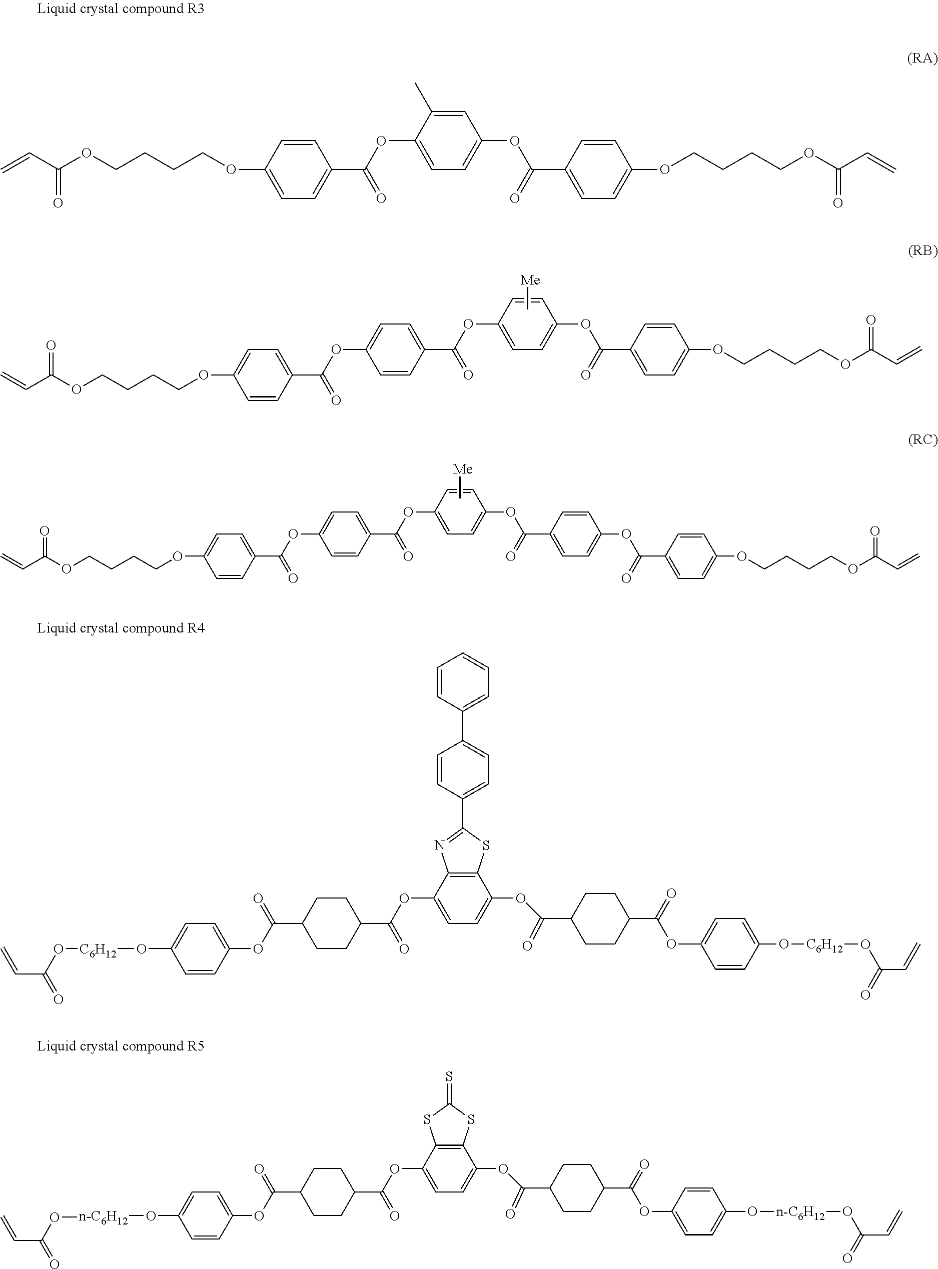

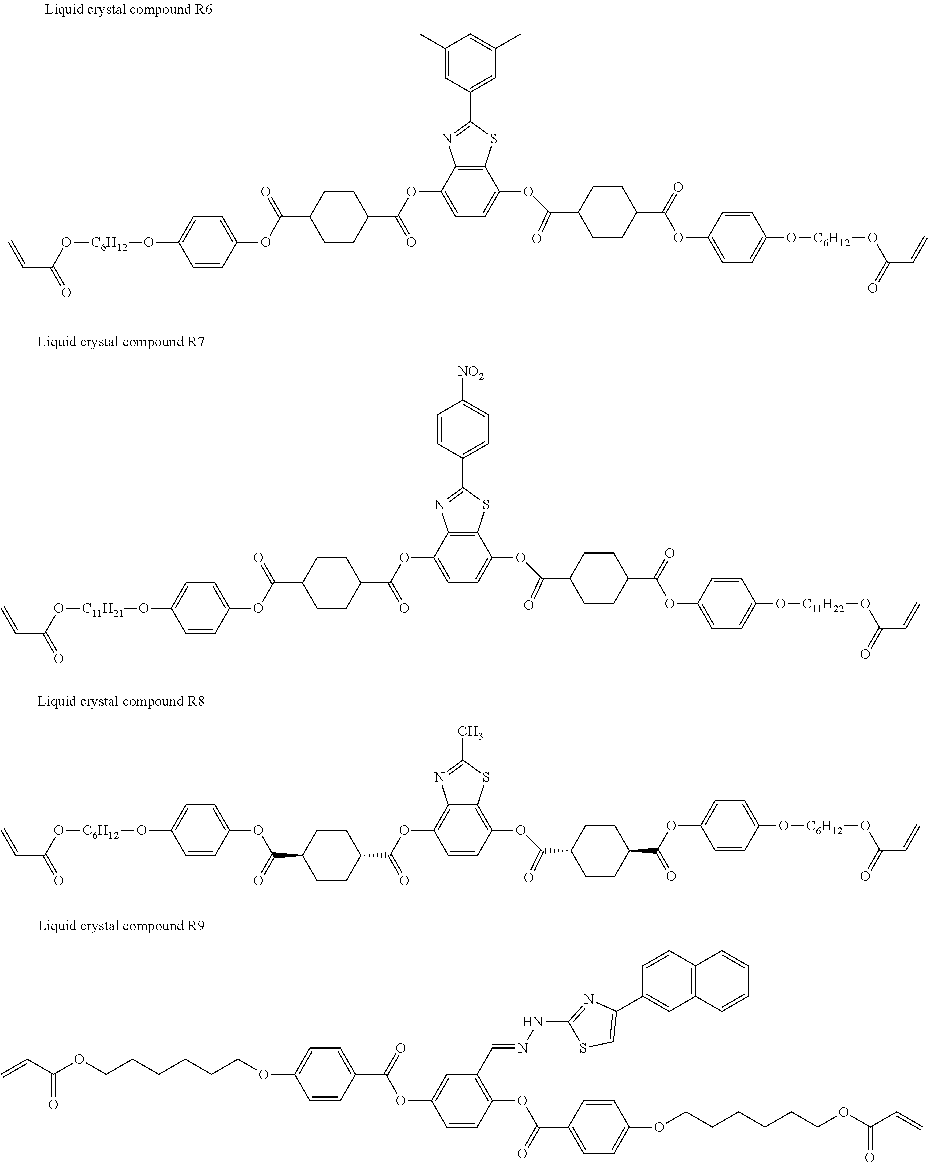

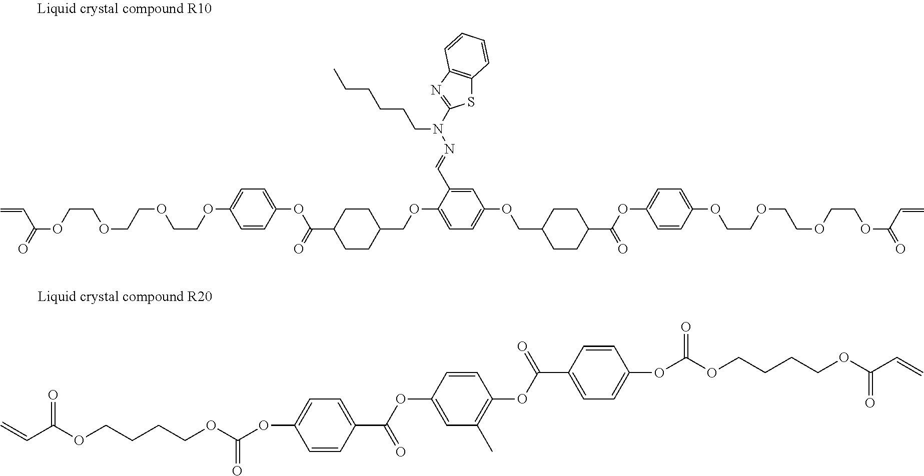

From the results shown in Tables 5 and 6, it was found that the polarizing plate using the optical film exhibiting forward wavelength dispersibility has neither a problem in an adhesiveness between the polarizer and the optical film nor a problem of deteriorated durability

### Reference Example 1

In addition, it can be seen that in a case where the polarizing plate using an optical film exhibiting reverse wavelength dispersibility does not satisfy the above-mentioned condition 1 or condition 2, the adhesiveness between the polarizer and the optical film is deteriorated and the durability is also deteriorated (Comparative Examples 1 to 3).

In contrast, it can be seen that even in the polarizing plate using an optical film exhibiting reverse wavelength dispersibility, in a case where the polymerization initiator satisfies the above-mentioned condition 1 or condition 2, the adhesiveness between the polarizer and the optical film is deteriorated and the durability is also deteriorated (Comparative Examples 1 to 13).

In particular, from a comparison between Examples 1 and 11, it was found that in a case where a polymer having a repeating unit represented by Formula (B) is present on a surface of the optical film on the adhesive layer side, the adhesiveness between the polarizer and the optical film is further improved.

In addition, from a comparison between Examples 1 and 12, it was found that in a case where the optical film has an optically anisotropic layer in which a liquid crystal state of a smectic phase is immobilized, the front surface CR of the liquid crystal display device is improved.

Moreover, from the comparison between Examples 1 and 13, it was found that the durability of the polarizing plate is further improved with the adhesive composition containing the sensitizer.

### Example 14

A first polarizing plate was manufactured by the same method as in Example 1, except that the second optically anisotropic layer was not formed.

In addition, in a case where the adhesiveness and the durability of the manufactured first polarizing plate were evaluated by the same method as in Example 1, the evaluation results on the adhesiveness and the durability were “B” and “A”, respectively, as shown in Table 7 below.

### Example 15

A first polarizing plate was manufactured by the same method as in Example 1, except that the composition 1 for forming an optically anisotropic layer was changed to the composition 3 for forming an optically anisotropic layer described below and the second optically anisotropic layer was not formed. Furthermore, it was confirmed by the method described above that in Example 15, the leveling agent P3 was present on a surface of the first optically anisotropic layer on the adhesive layer side.

In addition, in a case where the adhesiveness and the durability of the manufactured first polarizing plate were evaluated by the same method as in Example 1, any of the evaluation results were “A”, as shown in Table 7 below.

Composition 3 for forming optically anisotropic layer

| | |
|---|---|
| The liquid crystal compound R1 | 42.00 parts by mass |
| The liquid crystal compound R2 | 42.00 parts by mass |
| The polymerizable compound A1 | 12.00 parts by mass |
| The polymerizable compound A2 | 4.00 parts by mass |
| The polymerization initiator S1 | 0.50 parts by mass |
| The leveling agent P3 | 0.23 parts by mass |
| HISOLVE MTEM (manufactured by Toho | 2.00 parts by mass |
| Chemical Industry Co., Ltd.) | |
| NK ESTER A-200 (manufactured by Shin | 1.00 part by mass |
| Nakamura Chemical Co., Ltd.) | |
| Methyl ethyl ketone | 424.8 parts by mass |

TABLE 7

| | Optical Film | | | | | | |
|---|---|---|---|---|---|---|---|
| | | | Liquid crystal | | | | |
| | | | compound used | | | | |
| | | | for forming | | Wavelength | | Polymer |
| | | | first | Minimum | (nm) with | First | present on |
| | | | optically | absorption | transmittance | optically | surface on |
| | Re(450)/ | Re(650)/ | anisotropic | wavelength | of 1% or | anisotropic | adhesive |
| | Re(550) | Re(550) | layer | (nm) | more | layer | layer side |
| Example 14 | 0.86 | 1.03 | Liquid crystal | 300 | ≥380 | Sm phase | None |
| | | | compound R1 | | | | |
| | | | Liquid crystal | | | | |
| | | | compound R2 | | | | |
| Example 15 | 0.86 | 1.03 | Liquid crystal | 300 | ≥380 | Sm phase | Leveling |
| | | | compound R1 | | | | agent P3 |
| | | | Liquid crystal | | | | |
| | | | compound R2 | | | | |

| | Adhesive composition used for | | | | | |
|---|---|---|---|---|---|---|
| | manufacturing first polarizing plate | | | | | |
| | | Maximum | | | | |
| | | absorption | Molar | Maximum | | |
| | | wavelength | absorption | absorption | | |
| | | (nm) of | coefficient of | wavelength | Evaluation | |
| | Polymerizable | polymerization | polymerization | (nm) of | Adhe- | Dura- |
| | compound | initiator | initiator | sensitizer | siveness | bility |
| Example 14 | Epoxy | 320 | Irgacore 290 | 382 | B | A |
| | | | 75000 | | | |
| Example 15 | Epoxy | 320 | Irgacore 290 | 382 | A | A |
| | | | 75000 | | | |

### Example 16

A first polarizing plate was manufactured by the same method as in Example 1, except that the composition 1 for forming an optically anisotropic layer was changed to the composition 4 for forming an optically anisotropic layer and the composition 2 for forming an optically anisotropic layer was changed to the composition 5 for forming an optically anisotropic layer.

In addition, in a case where the adhesiveness and the durability of the manufactured first polarizing plate were evaluated by the same method as in Example 1, any of the evaluation results were “A”, as shown in Table 8 below.

Composition 4 for forming optically anisotropic layer

| | |
|---|---|
| The following liquid crystal compound R21 | 20.00 parts by mass |
| The following liquid crystal compound R22 | 27.00 parts by mass |
| The following liquid crystal compound R23 | 16.50 parts by mass |
| The following liquid crystal compound R24 | 16.50 parts by mass |
| The liquid crystal compound R2 | 20.00 parts by mass |
| The following polymerizable compound A3 | 15.00 parts by mass |
| NK Ester DCP (manufactured by Shin | 3.00 parts by mass |
| Nakamura Chemical Co., Ltd.) | |
| The polymerization initiator S1 | 1.50 parts by mass |
| DIPEA (manufactured by Koei Chemical Co., Ltd.) | 0.04 parts by mass |
| The leveling agent P1 | 0.12 parts by mass |
| Cyclopentanone | 214.9 parts by mass |
| Methyl ethyl ketone | 64.2 parts by mass |

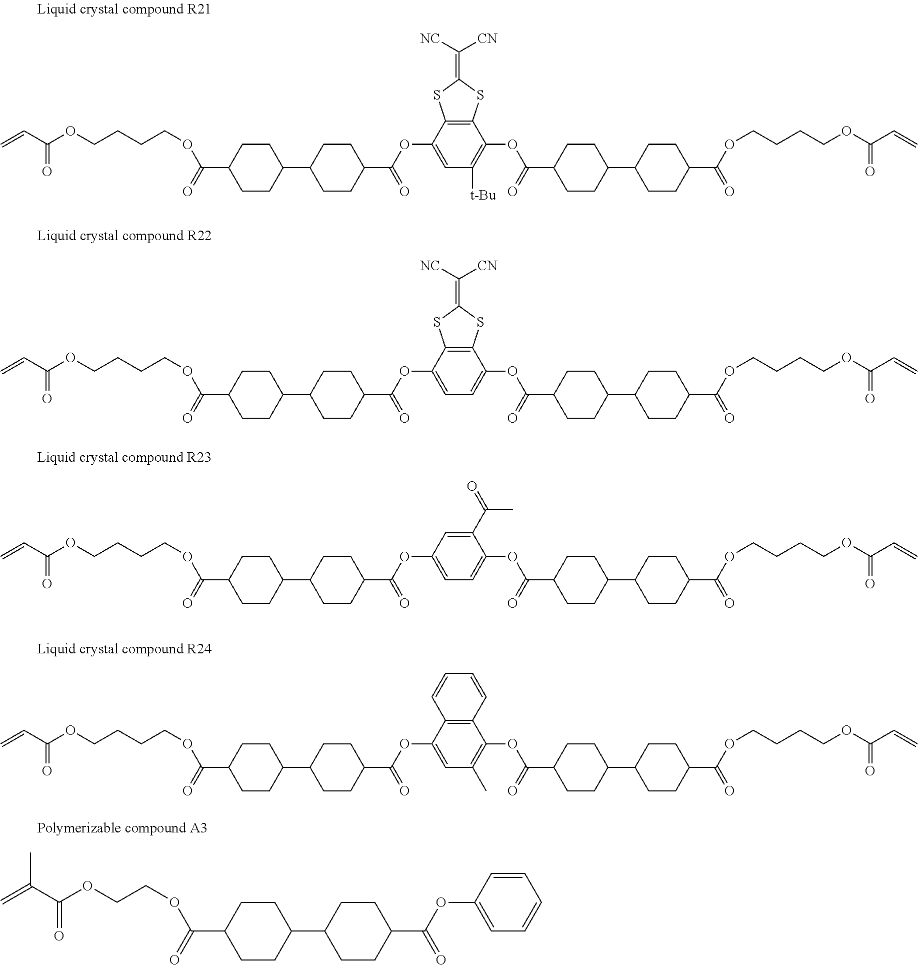

Composition 5 for forming optically anisotropic layer

| | |
|---|---|
| The liquid crystal compound R21 | 24.80 parts by mass |
| The liquid crystal compound R22 | 24.80 parts by mass |
| The liquid crystal compound R23 | 20.20 parts by mass |
| The liquid crystal compound R24 | 20.20 parts by mass |
| The liquid crystal compound R2 | 10.00 parts by mass |
| The polymerizable compound A3 | 15.00 parts by mass |
| DPHA (manufactured by Daicel Corporation) | 8.00 parts by mass |
| The compound B1 | 3.00 parts by mass |
| The polymerization initiator S1 | 3.00 parts by mass |
| The leveling agent P2 | 0.21 parts by mass |
| The leveling agent P3 | 0.21 parts by mass |
| Cyclopentanone | 233.0 parts by mass |
| Methyl ethyl ketone | 116.5 parts by mass |
| Isopropanol | 19.4 parts by mass |
| Methanol | 19.4 parts by mass |

TABLE 8

| | Optical Film | | | | | | | |
|---|---|---|---|---|---|---|---|---|
| | | | Liquid crystal | Liquid crystal | | | | |
| | | | compound used | compound used | | | | |
| | | | for forming | for forming | | Wavelength | | Polymer |
| | | | first | second | Minimum | (nm) with | First | present on |
| | | | optically | optically | absorption | transmittance | optically | surface on |
| | Re(450)/ | Re(650)/ | anisotropic | anisotropic | wavelength | of 1% or | anisotropic | adhesive |
| | Re(550) | Re(550) | layer | layer | (nm) | more | layer | layer side |
| Example 16 | 0.86 | 1.03 | Liquid crystal | Liquid crystal | 300 | ≥380 | Sm phase | Leveling |
| | | | compound R2 | compound R2 | | | | agent P3 |
| | | | Liquid crystal | Liquid crystal | | | | |
| | | | compound R21 | compound R21 | | | | |
| | | | Liquid crystal | Liquid crystal | | | | |
| | | | compound R22 | compound R22 | | | | |
| | | | Liquid crystal | Liquid crystal | | | | |
| | | | compound R23 | compound R23 | | | | |
| | | | Liquid crystal | Liquid crystal | | | | |
| | | | compound R24 | compound R24 | | | | |

| | Adhesive composition used for | | | | | | | |
|---|---|---|---|---|---|---|---|---|
| | manufacturing first polarizing plate | | | | | | | |
| | | Maximum | | | | | | |
| | | absorption | Molar | Maximum | Evaluation | | | |
| | | wavelength | absorption | absorption | Front | | | |
| | | (nm) of | coefficient of | wavelength | surface | Oblique | | |
| | Polymerizable | polymerization | polymerization | (nm) of | CR | light leak | Adhe- | Dura- |
| | compound | initiator | initiator | sensitizer | implemented | implemented | siveness | bility |
| Example 16 | Epoxy | 320 | Irgacore 290 | 382 | A | A | A | A |
| | | | 75000 | | | | | |

What is claimed is:

1. A polarizing plate comprising, adjacently in the following order:
a polarizer;
an adhesive layer; and
an optical film exhibiting reverse wavelength dispersibility,
wherein the adhesive layer is a layer formed of an adhesive composition containing a polymerizable compound and a polymerization initiator, and
the polarizing plate satisfies conditions 1 and 2 shown below,
condition 1: a maximum absorption wavelength of the polymerization initiator is within ±70 nm of a minimum absorption wavelength of the optical film, and
condition 2: a molar absorption coefficient of the polymerization initiator is 22,000 mol⁻¹Lcm⁻¹ or more.

2. The polarizing plate according to claim 1,
wherein the optical film has an optically anisotropic layer formed of a polymerizable liquid crystal composition containing a polymerizable liquid crystal compound.

3. The polarizing plate according to claim 2,
wherein the polymerizable liquid crystal compound is a compound having a linking group represented by any of Formulae (Ar-1) to (Ar-7), 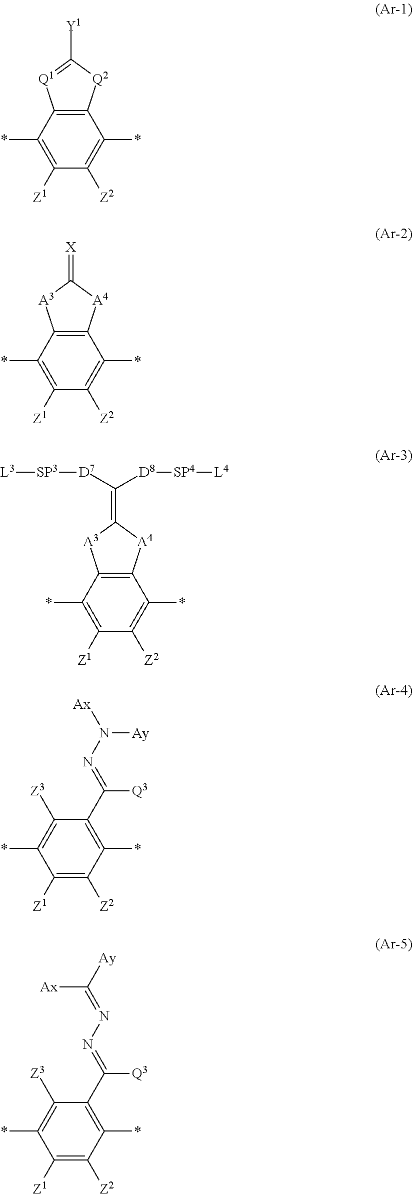 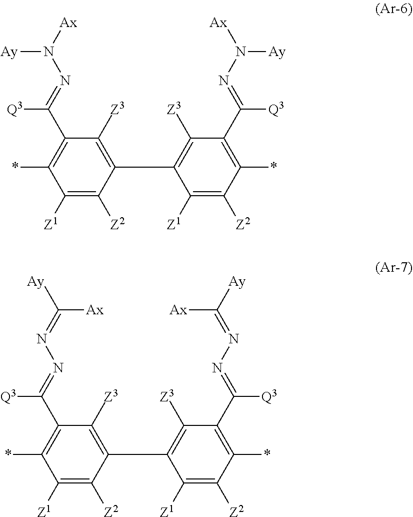
in Formulae (Ar-1) to (Ar-7),
* represents a bonding position,
Q¹ represents N or CH,
Q² represents —S—, —O—, or —N(R⁶)—, where R⁶ represents a hydrogen atom or an alkyl group having 1 to 6 carbon atoms,
Y¹ represents an aromatic hydrocarbon group having 6 to 12 carbon atoms, which may have a substituent, an aromatic heterocyclic group having 3 to 12 carbon atoms, which may have a substituent, or an alicyclic hydrocarbon group having 6 to 20 carbon atoms, which may have a substituent, and one or more of —CH₂-'s constituting the alicyclic hydrocarbon group may be substituted with —O—, —S—, or —NH—,
Z¹, Z², and Z³ each independently represent a hydrogen atom, a monovalent aliphatic hydrocarbon group having 1 to 20 carbon atoms, a monovalent alicyclic hydrocarbon group having 3 to 20 carbon atoms, a monovalent aromatic hydrocarbon group having 6 to 20 carbon atoms, a monovalent aromatic heterocyclic group having 6 to 20 carbon atoms, a halogen atom, a cyano group, a nitro group, —OR⁷, —NR⁸R⁹, —SR¹⁰, —COOR¹¹, or —COR¹², R⁷ to R¹² each independently represent a hydrogen atom or an alkyl group having 1 to 6 carbon atoms, and Z¹ and Z² may be bonded to each other to form an aromatic ring,
A³ and A⁴ each independently represent a group selected from the group consisting of —O—, —N(R¹³)—, —S—, and —CO—, where R¹³ represents a hydrogen atom or a substituent,
X represents a hydrogen atom or a non-metal atom of Groups XIV to XVI to which a substituent may be bonded,
D⁷ and D⁸ each independently represent a single bond; or —CO—, —O—, —S—, —C(═S)—, —CR¹R²—, —CR³═CR⁴—, —NR⁵—, or a divalent linking group consisting of a combination of two or more of these groups, where R¹ to R⁵ each independently represent a hydrogen atom, a fluorine atom, or an alkyl group having 1 to 12 carbon atoms,
SP³ and SP⁴ each independently represent a single bond, a linear or branched alkylene group having 1 to 12 carbon atoms, or a divalent linking group in which one or more of —CH₂-'s constituting the linear or branched alkylene group having 1 to 12 carbon atoms are substituted with —O—, —S—, —NH—, —N(Q)-, or —CO—, where Q represents a substituent,
L³ and L⁴ each independently represent a monovalent organic group,
Ax represents an organic group having 2 to 30 carbon atoms, which has at least one aromatic ring selected from the group consisting of an aromatic hydrocarbon ring and an aromatic heterocyclic ring,
Ay represents a hydrogen atom, an alkyl group having 1 to 12 carbon atoms, which may have a substituent, or an organic group having 2 to 30 carbon atoms, which has at least one aromatic ring selected from the group consisting of an aromatic hydrocarbon ring and an aromatic heterocyclic ring,
the aromatic ring in each of Ax and Ay may have a substituent, and Ax and Ay may be bonded to each other to form a ring, and
Q³ represents a hydrogen atom or an alkyl group having 1 to 20 carbon atoms, which may have a substituent.

4. The polarizing plate according to claim 1,
wherein a polymer having a repeating unit represented by Formula (B) is present on a surface of the optical film on the adhesive layer side or a surface of the adhesive layer on the optical film side, 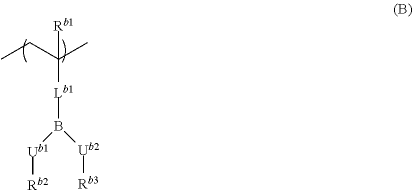
in Formula (B),
R^{b1} represents a hydrogen atom, a fluorine atom, a chlorine atom, or an alkyl group having 1 to 20 carbon atoms,
L^{b1} represents a single bond or a divalent linking group,
U^{b1} and U^{b2} each independently represent —O—, —S—, —COO—, —OCO—, —CONH—, —NHCOO—, or —NH—, and
R^{b2} and R^{b3} each independently represent a hydrogen atom, a substituted or unsubstituted aliphatic hydrocarbon group, a substituted or unsubstituted aryl group, or a substituted or unsubstituted heteroaryl group, provided that R^{b2} and R^{b3} may be bonded to each other through a linking group.

5. The polarizing plate according to claim 4,
wherein the polymer is a copolymer further having a repeating unit represented by Formula (F), 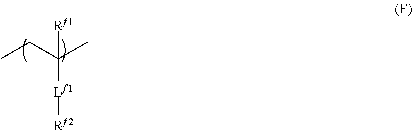
in Formula (F),
R^{f1} represents a hydrogen atom, a fluorine atom, a chlorine atom, or an alkyl group having 1 to 20 carbon atoms,
L^{f1} represents a single bond or a divalent linking group,
R^{f2} represents a group including at least one group of (a), (b), or (c),
(a) a group represented by any of Formulae (1) to (3),
(b) a perfluoropolyether group, and
(c) an alkyl group having a hydrogen bond between a proton donor functional group and a proton acceptor functional group, and having at least one carbon atom having a fluorine atom as a substituent and having 1 to 20 carbon atoms

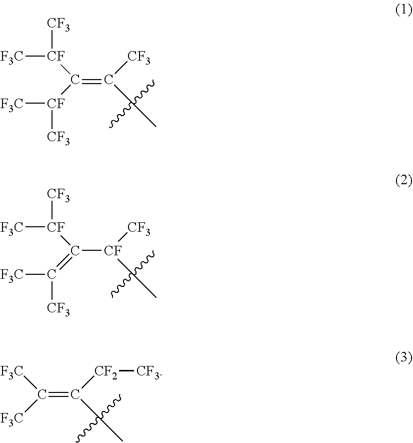

6. The polarizing plate according to claim 4,
wherein the polymer is present on a surface of the optical film on the adhesive layer side.

7. The polarizing plate according to claim 1,
wherein the optical film has at least one optically anisotropic layer where a liquid crystal state of a smectic phase is immobilized.

8. The polarizing plate according to claim 1,
wherein the adhesive composition further contains a sensitizer, and
the sensitizer has a maximum absorption wavelength that is on a longer wavelength side than a maximum absorption wavelength of the polymerization initiator and in a wavelength range where a transmittance of the optical film is 1% or more.

9. The polarizing plate according to claim 1,
wherein the polymerizable compound is a cationically polymerizable compound.

10. The polarizing plate according to claim 1,
wherein the polymerizable compound is a radically polymerizable compound.

11. An image display device comprising the polarizing plate according to claim 1.

12. The image display device according to claim 11,
wherein the image display device is a liquid crystal display device.

13. The image display device according to claim 11,
which is an organic electroluminescent display device.
